(19) United States
(12) Patent Application Publication
(10) Pub. No.: US 2026/0114037 A1
(43) Pub. Date: Apr. 23, 2026

(54) Gate Engineering for Stacked Device Structures

(71) Applicant: Taiwan Semiconductor Manufacturing Company, Ltd., Hsin-Chu (TW)

(72) Inventors: Chun-Da LIAO, Taipei City (TW); Kai-Chieh YANG, Hsinchu (TW); Shih-Hao LIN, Hsinchu (TW); Chih-Hsiang HUANG, Hsinchu County (TW)

(21) Appl. No.: 19/079,770

(22) Filed: Mar. 14, 2025

Related U.S. Application Data
(60) Provisional application No. 63/709,757, filed on Oct. 21, 2024.

(51) Int. Cl. H10D 84/85; H10D 30/00; H10D 30/01; H10D 30/43; H10D 62/10; H10D 64/66; H10D 64/68; H10D 84/01

(52) U.S. Cl. CPC H10D 84/851; H10D 30/014; H10D 30/019; H10D 30/43; H10D 30/502; H10D 62/121; H10D 64/667; H10D 64/669; H10D 64/685; H10D 84/0177; H10D 84/856

(57) ABSTRACT

An exemplary stacked device structure includes a semiconductor layer stack disposed over a substrate and a dual work function metal (DWFM) gate. The semiconductor layer stack includes a first semiconductor layer disposed over a second semiconductor layer. The DWFM gate includes a first gate dielectric layer, a second gate dielectric layer, a first type work function metal layer, and a second type work function metal layer. The first gate dielectric layer is disposed over the first semiconductor layer, and the second gate dielectric layer is disposed over the second semiconductor layer. The first type work function metal layer is disposed over the first gate dielectric layer, and the second type work function metal layer is disposed over the second gate dielectric layer. At least one of the first type work function metal layer or the second type work function metal layer has a gradient composition.

This is a non-provisional application of and claims benefit of U.S. Provisional Patent Application Ser. No. 63/709,757, filed Oct. 21, 2024, the entire disclosure of which is incorporated herein by reference.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, by reducing minimum IC feature size), and more recently, by introducing stacked device structures to enable further density reduction. However, such scaling has also increased IC device and manufacturing complexity. Improvements are thus needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a cross-sectional view of a stacked device structure, in portion or entirety, having a dual work function metal gate, according to various aspects of the present disclosure.

FIG. 1B and FIG. 1C are cross-sectional views of the stacked device structure of FIG. 1A, in portion or entirety, according to various aspects of the present disclosure.

FIGS. 2-7 depict various configurations of a dual function metal gate, in portion or entirety, which may be implemented in a gate of the stacked device structure of FIGS. 1A-1C, according to various aspects of the present disclosure.

FIG. 8 and FIG. 9 are cross-sectional views of other configurations of a dual work function metal gate of the stacked device structure of FIG. 1A, in portion or entirety, according to various aspects of the present disclosure.

FIG. 10 is a flow chart of a method, in portion or entirety, for fabricating a gate of a stacked device structure, such as a dual work function metal gate of the stacked device structure of FIGS. 1A-1C, according to various aspects of the present disclosure.

FIG. 11A is a cross-sectional view of another stacked device structure, in portion or entirety, according to various aspects of the present disclosure.

FIG. 11B and FIG. 11C are cross-sectional views of the stacked device structure of FIG. 11A, in portion or entirety, according to various aspects of the present disclosure.

FIGS. 12-14 depict various configurations of a p-type work function metal layer, in portion or entirety, which may be implemented in a gate of the stacked device structure of FIGS. 11A-11C, according to various aspects of the present disclosure.

FIG. 15 depicts a deposition process, in portion or entirety, that may be implemented when fabricating a gate of a stacked device structure, such as the gate of the stacked device structure of FIGS. 11A-11C, according to various aspects of the present disclosure.

FIG. 16 is a flow chart of a method, in portion or entirety, for fabricating a gate of a stacked device structure, such as a dual work function metal gate of the stacked device structure of FIGS. 11A-11C, according to various aspects of the present disclosure.

FIGS. 17A-17E are cross-sectional views are a stacked device structure, such as the stacked device structure of FIGS. 11A-11C, in portion or entirety, at various fabrication stages associated with the method of FIG. 16 according to various aspects of the present disclosure.

### DETAILED DESCRIPTION

The present disclosure relates generally to stacked device structures, such as transistor stacks having n-type transistors and p-type transistors (i.e., complementary field effect transistors (CFETs)), and more particularly, to gate engineering techniques for stacked device structures.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Stacked device structures provide further density reduction for advanced integrated circuit (IC) technology nodes (particularly as they advance to 3 nm (N3) and below), especially when the stacked device structures include multigate devices, such as fin-like field effect transistors (FinFETs), gate-all-around (GAA) transistors including nanowires and/or nanosheets, other types of multigate devices, etc. Stacked device structures vertically stack devices, such as transistors. For example, a transistor stack may include a first transistor (e.g., a top transistor) disposed over a second transistor (e.g., a bottom transistor). The transistor stack may provide a complementary field effect transistor (CFET) when the first transistor and the second transistor are of opposite conductivity type (i.e., an n-type transistor and a p-type transistor).

The present disclosure provides gate engineering techniques for stacked device structures, such as stacked transistors. For example, dual work function metal (DWFM) gate stacks are disclosed herein having improved diffusion blocking capabilities (e.g., reduced diffusion of aluminum from an n-type work function layer to a p-type work function layer of a DWFM gate stack), which may improve overall device performance. Such improvements are obtained by providing an n-type work function layer and/or a p-type work function layer of a DWFM gate stack with a varied composition (e.g., gradient composition). Details of the disclosed DWFM gate stacks, along with methods of fabrication thereof, are described herein.

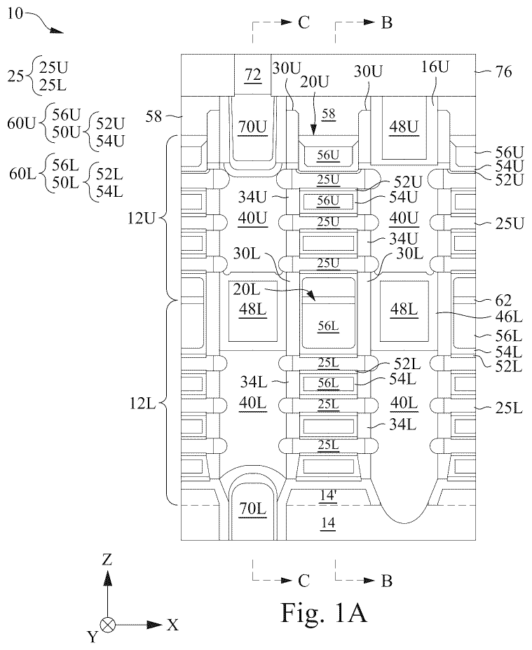

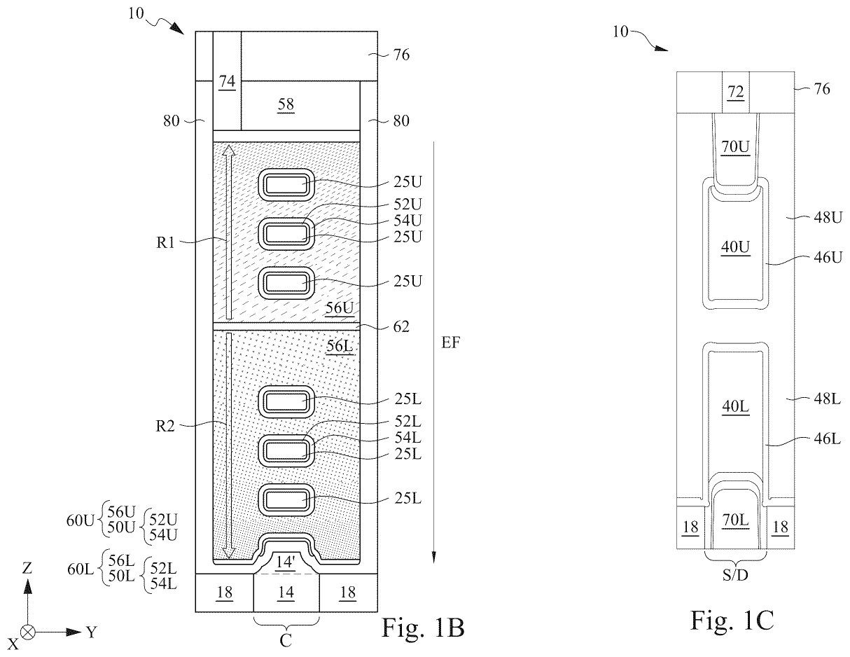

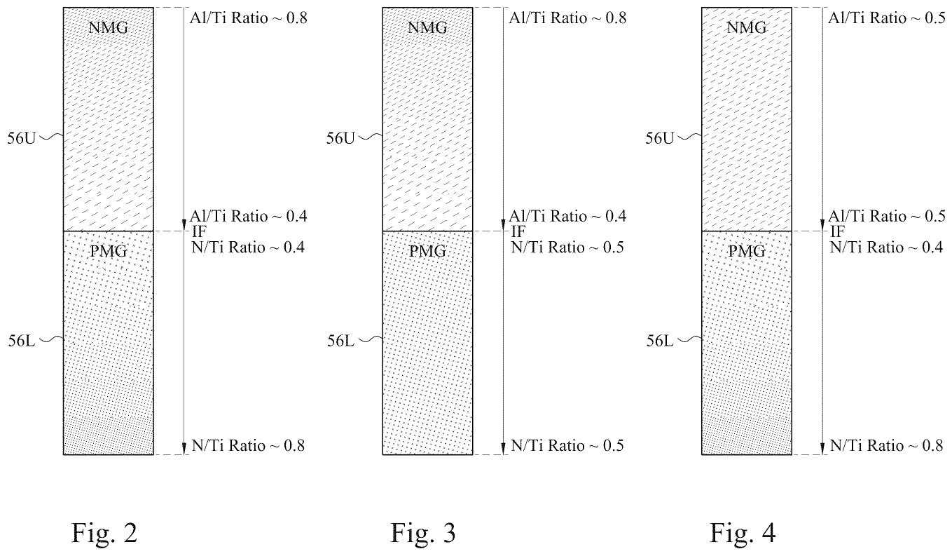

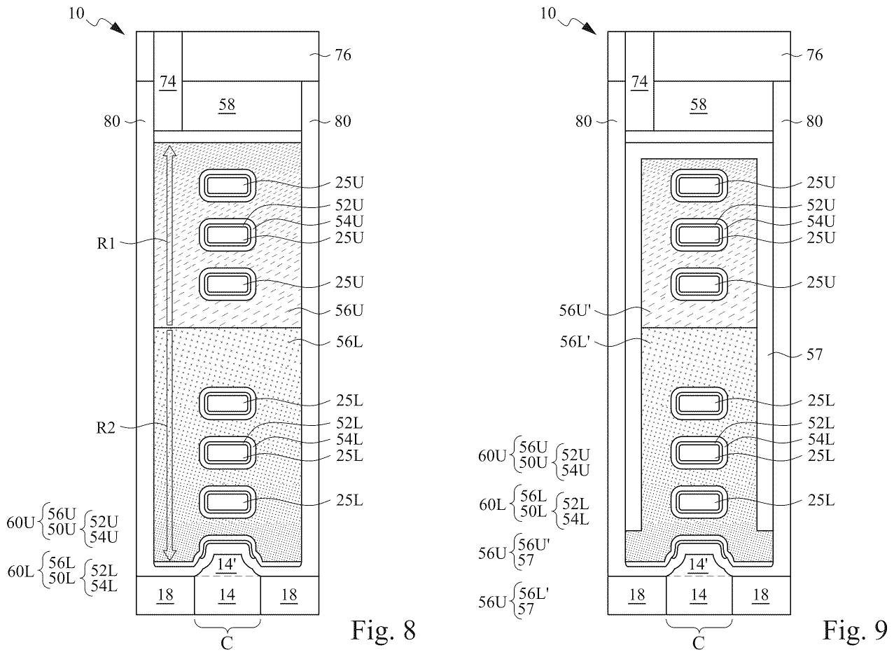

FIG. 1A is a cross-sectional view of a stacked device structure 10, in portion or entirety, according to various aspects of the present disclosure. FIG. 1B and FIG. 1C are cross-sectional views of stacked device structure 10, in portion or entirety, along line B-B and line C-C, respectively, of FIG. 1A, according to various aspects of the present disclosure. FIGS. 2-7 depict various dual work function metal (DWFM) configurations that may be implemented in a gate stack of stacked device structure 10, according to various aspects of the present disclosure. FIG. 8 and FIG. 9 are cross-sectional views of other embodiments of stacked device structure 10, in portion or entirety, along line B-B of FIG. 1A, according to various aspects of the present disclosure. FIGS. 1A-1C and FIGS. 2-9 have been simplified for the sake of clarity to better understand the inventive concepts of the present disclosure. Additional features may be added in stacked device structure 10, and some of the features described below may be replaced, modified, or eliminated in other embodiments of stacked device structure 10.

Stacked device structure 10 may include an upper device region 12U, a lower device region 12L, and a substrate 14. Upper device region 12U is disposed over lower device region 12L, and lower device region 12L is disposed over substrate 14. Upper device region 12U and lower device region 12L may each include at least one electrically functional device, and a device stack may be formed from an upper device in upper device region 12U and a lower device in lower device region 12L. For example, a transistor stack of stacked device structure 10 may include an upper transistor 20U stacked vertically over a lower transistor 20L. In the depicted embodiment, transistor 20U and transistor 20L are of an opposite conductivity type. For example, transistor 20U is an n-type transistor, and transistor 20L is a p-type transistor. In another example, transistor 20U is a p-type transistor, and transistor 20L is an n-type transistor. In such embodiments, transistor 20U and transistor 20L may form a CFET. In some embodiments, transistor 20U and transistor 20L are of a same conductivity type. For example, transistor 20U and transistor 20L may both be n-type transistors or p-type transistors.

Upper device region 12U includes various features and/or components, such as semiconductor layers 25U, gate spacers 30U, inner spacers 34U, source/drains 40U, a contact etch stop layer (CESL) 46U, an interlayer dielectric (ILD) layer 48U, gate dielectrics 50U (each of which may include a respective interfacial layer 52U and a respective high-k dielectric layer 54U), gate electrodes 56U, and hard masks 58. Lower device region 12L includes various features and/or components, such as mesas 14′ (which may be protrusions/extensions from and/or of substrate 14), substrate isolation structures 18, fin spacers, semiconductor layers 25L, gate spacers 30L, inner spacers 34L, source/drains 40L, a CESL 46L, an ILD layer 48L, gate dielectrics 50L (each of which may include a respective interfacial layer 52L and a respective high-k dielectric layer 54L), and gate electrodes 56L. A gate stack 60U of an upper transistor, such as transistor 20U, includes a respective gate dielectric 50U and a respective gate electrode 56U, and a gate stack 60L of a lower transistor, such as transistor 20L, includes a respective gate dielectric 50L and a respective gate electrode 56L. Gate stack 60U and gate stack 60L may collectively form a gate 60 (also referred to as a gate stack) of a device stack (e.g., a transistor stack) of stacked device structure. Gate 60 may provide a metal gate and/or a high-k/metal gate of a CFET. In the depicted embodiment, as described further below, where transistor 20U is an n-type transistor and transistor 20L is a p-type transistor, gate stack 60U and gate stack 60L may be configured with different type work function materials (e.g., n-type work function and p-type work function), such that gate 60 is a dual work function metal (DWFM) gate.

Transistor 20L may be configured as a GAA transistor. For example, transistor 20L includes three channels (e.g., nanowires, nanosheets, nanobars, or the like) provided by semiconductor layer 25L (also referred to as channel layers or channels), which are suspended over substrate 14 and extend between respective source/drains, such as source/drains 40L. In some embodiments, transistor 20L includes more or less channels (and thus more or less semiconductor layers 25L). Transistor 20L further includes gate stack 60L, which is disposed over semiconductor layers 25L and between its source/drains 40L. In FIG. 1A, gate stack 60L is between semiconductor layers 25L and between bottommost semiconductor layer 25L and substrate 14 (e.g., mesas 14′ thereof). In FIG. 1B, gate stack 60L wraps around semiconductor layers 25L. During operation, current may flow through semiconductor layers 25L and between source/drains 40L. Further, transistor 20L has gate spacers 30L disposed along sidewalls of an upper, topmost portion of gate stack 60L, inner spacers 34L disposed between gate stack 60L and source/drains 40L, and fin spacers disposed along sidewalls of mesas 14′.

Transistor 20U may be configured as a GAA transistor. For example, transistor 20U has three channels (e.g., nanowires, nanosheets, nanobars, or the like) provided by semiconductor layer 25U (also referred to as channel layers or channels), which are suspended over substrate 14 and extend between respective source/drains, such as source/drains 40U. In some embodiments, transistor 20U includes more or less channels (and thus more or less semiconductor layers 25U). Transistor 20U further includes gate stack 60U, which is disposed over semiconductor layers 25U and between its source/drains 40U. In FIG. 1A, gate stack 60U is over semiconductor layer 25U and between bottommost semiconductor layer 25U and gate stack 60L. In FIG. 1B, gate stack 60U wraps around semiconductor layer 25U. During operation, current may flow through semiconductor layer 25U and between respective source/drains 40U. Further, transistor 20U has gate spacers 30U disposed along sidewalls of an upper, topmost portion of gate stack 60U, inner spacers 34U disposed between gate stack 60U and source/drains 40U, and a respective hard mask 58 disposed over gate stack 60U. Hard mask 58 may be disposed between respective gate spacers 30U. In some embodiments, hard mask 58 may be considered a portion of gate stack 60U.

Substrate 14 (and mesa 14′), semiconductor layers 25U, and semiconductor layers 25L include an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. For example, substrate 14, semiconductor layers 25U, and semiconductor layers 25L are formed of silicon. In some embodiments, semiconductor layers 25U and semiconductor layers 25L are formed of different semiconductor materials, such as silicon and silicon germanium, respectively, or vice versa. In some embodiments, substrate 14 is a semiconductor-on-insulator substrate, such as a silicon-on-insulator (SOI) substrate, a silicon germanium-on-insulator (SGOI) substrate, or a germanium-on-insulator (GOI) substrate. Substrate 14 (and/or mesa 14′ extending therefrom) may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, gallium, other p-type dopant, or combinations thereof. In some embodiments, the doped regions include p-type dopants and n-type dopants. In some embodiments, semiconductor layers 25U and/or semiconductor layers 25L include p-type dopants, n-type dopants, or combinations thereof. For case of description herein, semiconductor layers 25U and semiconductor layers 25L may be referred to collectively as semiconductor layers 25.

Substrate isolation structures 18 are disposed over substrate 14, and substrate isolation structures 18 may be disposed adjacent to and/or around mesas 14′ (also referred to as a substrate extension, a substrate fin portion, a fin portion, a protrusion, an etched substrate portion, etc.). Substrate isolation structures 18 may electrically isolate an active device region, such as a channel region and/or source/drain regions, from other device regions. Substrate isolation structures 18 include silicon oxide, silicon nitride, silicon oxynitride, other suitable isolation material (including silicon, oxygen, nitrogen, carbon, other suitable isolation constituent, or combinations thereof), or combinations thereof. Substrate isolation structures 18 may have a multilayer structure. For example, substrate isolation structures 18 may include a bulk dielectric (e.g., an oxide layer) over a dielectric liner (e.g., silicon nitride, silicon oxide, silicon oxynitride, silicon oxycarbonitride, or combinations thereof). In another example, substrate isolation structures 18 may include a bulk dielectric over a doped liner, such as a boron silicate glass (BSG) liner and/or a phosphosilicate glass (PSG) liner. Dimensions and/or characteristics of substrate isolation structures 18 may be configured to provide shallow trench isolation (STI) structures, deep trench isolation (DTI) structures, local oxidation of silicon (LOCOS) structures, other suitable isolation structures, or combinations thereof.

Gate spacers 30U are disposed along sidewalls of top portions of gate stack 60U, gate spacers 30L are disposed along sidewalls of top portions of gate stack 60L, fin/mesa spacers may be disposed along sidewalls of mesa 14′, inner spacers 34U are disposed under gate spacers 30U and along sidewalls of gate stack 60U, and inner spacers 34L are disposed under gate spacers 30L and along sidewalls of gate stack 60L. Along a gate height direction, inner spacers 34U are between semiconductor layers 25U, and inner spacers 34L are between semiconductor layers 25L. Along a gate width direction, inner spacers 34U are between gate stack 60U and source/drains 40U, and inner spacers 34L are between gate stack 60L and source/drains 40L. Gate spacers 30U, gate spacers 30L, fin spacers, inner spacers 34U, and inner spacers 34L include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). Gate spacers 30U, gate spacers 30L, fin spacers, inner spacers 34U, inner spacers 34L, or combinations thereof may include different materials and/or different configurations (e.g., different numbers of layers). In some embodiments, gate spacers 30U, gate spacers 30L, fin spacers, inner spacers 34U, inner spacers 34L, or combinations thereof have a multilayer structure, such as two or more dielectric layers having different compositions. In some embodiments, gate spacers 30U and/or gate spacers 30L include more than one set of spacers, such as seal spacers, offset spacers, sacrificial spacers, dummy spacers, main spacers, or combinations thereof. The various sets of spacers may have different compositions.

Gate 60 is disposed between respective source/drain stacks. Each source/drain stack includes a respective source/drain 40U, a respective source/drain 40L, and a respective isolation structure (here, formed by ILD layer 48L and CESL 46L) therebetween. Source/drains 40U and source/drains 40L include semiconductor material(s) that may be doped with n-type dopants and/or p-type dopants. In some embodiments, source/drains 40U and/or source/drains 40L include silicon doped with carbon, phosphorous, arsenic, other n-type dopant, or combinations thereof (e.g., Si:C source/drains, Si:P source/drains, or Si:C:P source/drains). In some embodiments, source/drains 40U and/or source/drains 40L include silicon germanium or germanium, which is doped with boron and/or other p-type dopant (e.g., Si:Ge:B source/drains). Source/drains 40U and/or source/drains 40L may have the same or different compositions and/or materials depending on configurations of their respective transistors. For example, where transistor 20U is an n-type transistor and transistor 20L is a p-type transistor, source/drains 40U are configured for n-type transistors, and source/drains 40L are configured for p-type transistors. For example, source/drains 40U include silicon doped with n-type dopant (e.g., carbon), and source/drains 40L include silicon germanium and/or germanium doped with p-type dopant (e.g., boron). In some embodiments, source/drains 40U and/or source/drains 40L have a multilayer structure. For example, source/drains 40U and/or source/drains 40L may include semiconductor layers having different compositions, and the different compositions may be achieved by configuring the semiconductor layers with different semiconductor materials, different dopants, different atomic percentages of constituents thereof, different dopant concentrations, or combinations thereof. In some embodiments, source/drains 40L and/or source/drains 40U include materials and/or dopants that achieve desired tensile stress and/or compressive stress in adjacent channel regions (e.g., formed by semiconductor layers 25U and semiconductor layers 25L). The present disclosure further contemplates embodiments where transistor 20U is a p-type transistor, transistor 20L is an n-type transistor, source/drains 40U are configured for p-type transistors, and source/drains 40L are configured for n-type transistors. As used herein, source/drain, source/drain region, epitaxial source/drain, epitaxial source/drain feature, etc. may refer to a source of a device (e.g., transistor 20U or transistor 20L), a drain of a device (e.g., transistor 20U or transistor 20L), or a source and/or a drain of multiple devices.

ILD layer 48U and ILD layer 48L include a dielectric material, which may include silicon oxide, silicon nitride, silicon oxynitride, tetraethylorthosilicate-formed (TEOS) oxide, carbon doped silicon oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or combinations thereof. In some embodiments, ILD layer 48U and/or ILD layer 48L include a low-k dielectric material having a dielectric constant that is less than a dielectric constant of silicon dioxide (e.g., k<3.9). In some embodiments, ILD layer 48U and/or ILD layer 48L include a dielectric material having a dielectric constant that is less than about 2.5 (i.e., an extreme low-k (ELK) dielectric material), such as porous silicon dioxide, silicon carbide, carbon-doped oxide (e.g., a SiCOH-based material having, for example, Si—CH₃ bonds), or combinations thereof, each of which may be tuned/configured to exhibit a dielectric constant less than about 2.5. ILD layer 48U and ILD layer 48L may include different materials and/or different configurations (e.g., different numbers of layers). CESL 46U includes a material different than ILD layer 48U, such as a dielectric material that is different than the dielectric material of ILD layer 48U, and CESL 46L includes a material different than ILD layer 48L, such as a dielectric material that is different than the dielectric material of ILD layer 48L. For example, where ILD layer 48U and ILD layer 48L include a silicon-and-oxygen comprising low-k dielectric material, CESL 46U and CESL 46L may include silicon and nitrogen and/or carbon, such as silicon nitride, silicon carbonitride, silicon oxycarbonitride, or combinations thereof. In some embodiments, CESL 46U and/or CESL 46L include metal and oxygen, nitrogen, carbon, or combinations thereof. CESL 46U and CESL 46L may include different materials and/or different configurations, such as different numbers of layers. ILD layer 48U, ILD layer 48L, CESL 46U, CESL 46L, or combinations thereof may have a multilayer structure and/or include multiple dielectric materials.

Gate dielectric 50U is disposed on semiconductor layers 25U, and gate dielectric 50L is disposed on semiconductor layers 25L. Gate dielectric 50U may further be disposed on gate spacers 30U and/or inner spacers 34U, and gate dielectric 50L may further be disposed on gate spacers 30L and/or inner spacers 34L. Gate dielectric 50U and gate dielectric 50L each include at least one dielectric layer. For example, gate dielectric 50U includes interfacial layer 52U and high-k dielectric layer 54U, and gate dielectric 50L includes interfacial layer 52L and high-k dielectric layer 54L. Interfacial layer 52U is disposed between high-k dielectric layer 54U and semiconductor layers 25U, and interfacial layer 52L is disposed between high-k dielectric layer 54L and semiconductor layers 25L. Interfacial layer 52U and interfacial layer 52L each include a dielectric material, such as SiO₂, SiGeO, HfSiO, SiON, other dielectric material, or combinations thereof. Interfacial layer 52U and interfacial layer 52L may include the same or different materials and/or configurations, such as different numbers/compositions of layers.

High-k dielectric layer 54U is disposed between gate electrode 56U and semiconductor layers 25U, gate electrode 56U and gate spacers 30U, and gate electrode 56U and inner spacers 34U. High-k dielectric layer 54L is disposed between gate electrode 56L and semiconductor layers 25L, gate electrode 56L and gate spacers 30L, gate electrode 56L and inner spacers 34L, and gate electrode 56L and substrate 14 (e.g., mesas 14′ thereof). High-k dielectric layer 54U and high-k dielectric layer 54L each include a high-k dielectric material, which generally refers to a dielectric material having a dielectric constant greater than a dielectric constant of silicon dioxide, such as HfO₂, HfSiO, HfSiO₄, HfSiON, HfLaO, HfTaO, HITiO, HfZrO, HfAlOx, ZrO, ZrO₂, ZrSiO₂, AIO, AlSiO, Al₂O₃, TiO, TiO₂, LaO, LaSiO, LaO₃, La₂O₃, Ta₂O₃, Ta₂O₃, Y₂O₃, SrTiO₃, BaZrO, BaTiO₃ (BTO), (Ba,Sr)TiO₃ (BST), HfO₂—Al₂O₃, other high-k dielectric material, or combinations thereof. In some embodiments, high-k dielectric layer 54U and/or high-k dielectric layer 54L include a hafnium-based oxide (e.g., HfO₂) layer. In some embodiments, high-k dielectric layer 54U and/or high-k dielectric layer 54L include a zirconium-based oxide (e.g., ZrO₂) layer. High-k dielectric layer 54U and high-k dielectric layer 54L may include the same or different compositions and/or configurations.

Gate electrode 56U is disposed on gate dielectric 50U, and gate electrode 56L is disposed on gate dielectric 50L. Gate electrode 56U and gate electrode 56L each include at least one electrically conductive layer. In the depicted embodiment, gate electrode 56L includes a p-type work function metal (PWFM) layer (also referred to as a p-metal layer) and gate electrode 56U includes an n-type work function metal (NWFM) layer (also referred to as an n-metal layer). The PWFM layer includes a p-type work function metal material, which generally refers to an electrically conductive material having a p-type work function, and the NWFM layer includes an n-type work function metal material, which generally refers to an electrically conductive material having an n-type work function. The p-type work function metal material may include titanium, tantalum, ruthenium, molybdenum, tungsten, palladium, platinum, iridium, other p-metal, alloys thereof, or combinations thereof. For example, the PWFM layer may be a titanium nitride layer, a molybdenum nitride layer, a palladium layer, a platinum layer, an iridium layer, a ruthenium layer, or combinations thereof. The n-type work function metal material may include aluminum, titanium, tantalum, zirconium, other n-metal, alloys thereof, or combinations thereof. For example, the NWFM layer may be a titanium aluminum layer, a titanium aluminum carbide layer, a tantalum layer, a tantalum aluminum layer, a tantalum aluminum carbide layer, or combinations thereof. In some embodiments, the PWFM layer has a multilayer structure (e.g., more than one PWFM layer), and/or the NWFM layer has a multilayer structure.

In the depicted embodiment, the NWFM layer (i.e., gate electrode 56U) includes titanium and aluminum, and the PWFM layer (i.e., gate electrode 56L) includes titanium and nitrogen. For example, the NWFM layer is a titanium aluminum layer, and the PWFM layer is a titanium nitride layer. The present disclosure recognizes that diffusion of aluminum from the NWFM layer into the PWFM layer may decrease an aluminum content/concentration in the NWFM layer and introduce aluminum into and/or increase an aluminum content/concentration of the PWFM layer, thereby undesirably changing (e.g., increasing) a threshold voltage of the n-type transistor and/or a threshold voltage of the p-type transistor. The present disclosure further recognizes that intermixing of constituents of the NWFM layer and the PWFM layer (e.g., aluminum and nitrogen) at an interface thereof may also cause undesired threshold voltage changes. To inhibit such diffusion of constituents from the NWFM layer into the PWFM layer and/or intermixing of the constituents of the NWFM layer and the PWFM layer, the present disclosure provides the NWFM layer and the PWFM layer with gradient compositions. For example the NWFM layer (i.e., gate electrode 56U) has a gradient aluminum/titanium (Al/Ti) ratio, such as an Al/Ti ratio that decreases from top to bottom thereof, as indicated by arrow R1, and the PWFM layer (i.e., gate electrode 56L) has a gradient nitrogen/titanium (N/Ti) ratio, such as an N/Ti ratio that increases from top to bottom thereof, as indicated by arrow R2. In some embodiments, the Al/Ti ratio decreases along a gate height direction from a top of gate stack 60U (which may interface with hard mask 58) to a bottom of gate stack 60U (which may interface with the PWFM layer and/or a work function barrier layer between the PWFM layer and the NWFM layer), and the N/Ti ratio increases along the gate height direction from a top of gate stack 60L (which may interface with the NWFM layer and/or a work function barrier layer between the NWFM layer and the PWFM layer) to a bottom of gate stack 60L (which may interface with a portion of high-k dielectric layer 54L over substrate 14 and/or mesa 14′). Configuring gate electrode 56U with a top-heavy Al/Ti ratio and a bottom-light Al/Ti ratio and gate electrode 56L with a top-light N/Ti ratio and a bottom-heavy N/Ti reduces an amount of aluminum and nitrogen (e.g., concentrations thereof) at an interface of gate electrode 56U and gate electrode 56L (e.g., at an interface of the WFM layers thereof). Reducing the amount of aluminum and/or nitrogen may reduce diffusion of aluminum into gate electrode 56L and/or reduce intermixing of nitrogen of gate electrode 56L with constituents of gate electrode 56U (e.g., aluminum). Configuring gate electrode 56U and gate electrode 56U with gradient WFM layers may thus improve overall device performance and stability.

Referring to FIG. 2, in the depicted embodiment, both the NWFM layer and the PWFM layer are configured with gradient compositions. For example, the Al/Ti ratio in the NWFM layer may decrease from 0.8 to 0.4 from top to bottom of gate electrode 56U. In other words, the Al/Ti ratio in a top portion of the NWFM layer (e.g., a portion above topmost semiconductor layer 25U) is about 0.8, the Al/Ti ratio in a bottom portion of the NWFM layer (e.g., a portion above and/or below bottommost semiconductor layer 25U) is about 0.4, and the Al/Ti ratio in a middle portion of the NWFM layer (e.g., a portion around and/or proximate to middle semiconductor layer 25U) is between 0.8 and 0.4 (e.g., about 0.6). In furtherance of such example, the N/Ti ratio in the PWFM layer may increase from 0.4 to 0.8 from top to bottom of gate electrode 56L. In other words, the N/Ti ratio in a top portion of the PWFM layer (e.g., a portion above topmost semiconductor layer 25L) is about 0.4, the N/Ti ratio in a bottom portion of the PWFM layer (e.g., a portion above and/or below bottommost semiconductor layer 25L) is about 0.8, and the N/Ti ratio in a middle portion of the PWFM layer (e.g., a portion around and/or proximate to middle semiconductor layer 25L) is between 0.8 and 0.4 (e.g., about 0.6). In some embodiments, an atomic percent of aluminum may decrease along a thickness of the NWFM layer. In some embodiments, an atomic percent of nitrogen may increase along a thickness of the PWFM layer. In some embodiments, an atomic percent of aluminum in the NWFM layer and an atomic percent of nitrogen in the PWFM layer may be lowest at an interface of the NWFM layer and the PWFM layer, and the interface may or may not include a work barrier layer, such as described below, between the NWFM layer and the PWFM layer.

Referring to FIG. 3, in some embodiments, the NWFM layer has a gradient composition, and the PWFM layer has a uniform composition. For example, the Al/Ti ratio in the NWFM layer may decrease from 0.8 to 0.4 from top to bottom, and the N/Ti ratio in the PWFM layer may be constant (e.g., about 0.5) from top to bottom. In such example, an atomic percent of aluminum may decrease along a thickness of the NWFM layer, and/or an atomic percent of nitrogen and/or an atomic percent of titanium may be constant along a thickness of the PWFM layer. Referring to FIG. 4, in some embodiments, the NWFM layer has a uniform composition, and the PWFM layer has a gradient composition. For example, the Al/Ti ratio in the NWFM layer may be constant (e.g., about 0.5) from top to bottom, and the N/Ti ratio in the PWFM layer may increase from 0.4 to 0.8. In such example, an atomic percent of nitrogen may increase along a thickness of the NWFM layer, and/or an atomic percent of aluminum and/or an atomic percent of titanium may be constant along a thickness of the NWFM layer.

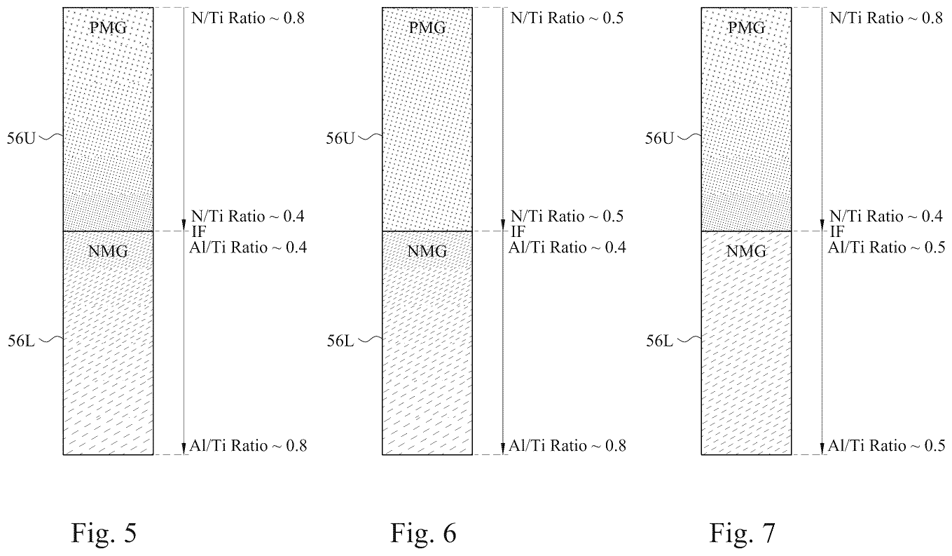

Referring to FIGS. 5-7, the present disclosure further contemplates embodiments where transistor 20U and transistor 20L are configured as a p-type transistor and an n-type transistor, respectively. In such embodiments, gate electrode 56U includes and/or is a PWFM layer, gate electrode 56L includes and/or is an NWFM layer, and gate 60 may be configured with both the PWFM layer and the NWFM layer having a gradient composition (FIG. 5), the PWFM layer having a constant composition and the NWFM layer having a gradient composition (FIG. 6), or the PWFM layer having a gradient composition and the NWFM layer having a constant composition (FIG. 7). In such embodiments, the gradient compositions may be configured differently than in the embodiments of FIGS. 2-4 to ensure an amount of aluminum and/or an amount of nitrogen is reduced at the PWFM layer/NWFM layer interface. For example, in FIG. 5, the N/Ti ratio in the PWFM layer may decrease, instead of increase, from 0.5 to 0.8, and the Al/Ti ratio in the NWFM layer may increase, instead of decrease, from 0.4 to 0.8 from top to bottom. In FIG. 6, the N/Ti ratio in the PWFM layer may be constant (e.g., about 0.5) from top to bottom, and the Al/Ti ratio in the NWFM layer may increase from 0.4 to 0.8 from top to bottom. In FIG. 7, the N/Ti ratio in the PWFM layer may decrease from 0.8 to 0.4, and the Al/Ti ratio in the NWFM layer may be constant (e.g., about 0.5) from top to bottom.

Referring again to FIGS. 1A-1C, gate 60 may include a barrier layer 62 between gate electrode 56U and gate electrode 56L. Barrier layer 62 is formed of a material that inhibits diffusion and/or intermixing of constituents of opposite type work function layers, such as the NWFM layer and the PWFM layer. For example, barrier layer 62 may reduce and/or eliminate diffusion of aluminum (and/or other constituents) from the NWFM layer into the PWFM layer, and barrier layer 62 may reduce and/or eliminate intermixing of constituents of the PWFM layer and the NWFM layer (e.g., nitrogen and aluminum, respectively). In some embodiments, barrier layer 62 includes titanium, tungsten, and nitrogen. For example, barrier layer 62 is a tungsten-doped TiN layer, such as a TiWN layer. In some embodiments, barrier layer 62 includes titanium, molybdenum, and nitrogen. For example, barrier layer 62 is a molybdenum-doped TiN layer, such as a TiMoN layer. In some embodiments, barrier layer 62 includes molybdenum and nitrogen. For example, barrier layer 62 is a molybdenum nitride (MoN) layer. Tungsten and/or molybdenum may inhibit diffusion of aluminum and/or other constituents from the NWFM layer into the PWFM layer, or vice versa, thereby minimizing undesired changes in threshold voltages of transistor 20U and transistor 20L. Incorporating a tungsten-containing and/or molybdenum-containing film, such as barrier layer 62, at an interface between the NWFM layer and the PWFM layer may thus improve overall device performance and stability. In some embodiments, barrier layer 62 has a multilayer structure, such as a TiWN layer and a MON layer.

The present disclosure further contemplates embodiments that omit barrier layer 62, such as depicted in FIG. 8. In such embodiments, gate electrode 56U abuts gate electrode 56L (e.g., the NWFM layer abuts the PWFM layer) and constituent intermixing therebetween may be reduced and/or eliminated by configuring gate electrode 56U and/or gate electrode 56L with gradient compositions, such as described above. For example, the NWFM layer may have a gradient Al/Ti ratio, and/or the PWFM layer may have a gradient N/Ti ratio.

The present disclosure further contemplates embodiments where gate 60 includes a metal fill/bulk layer 57, such as depicted in FIG. 9. In such embodiments, the at least one electrically conductive gate layer of gate electrode 56U may include an NWFM layer (e.g., WFM layer 56U′), such as described above, and metal fill/bulk layer 57, and the at least one electrically conductive gate layer of gate electrode 56L may include a PWFM layer (e.g., WFM layer 56L′), such as described above, and metal fill/bulk layer 57. Metal fill/bulk layer 57 includes aluminum, tungsten, cobalt, copper, other suitable electrically conductive material, alloys thereof, or combinations thereof. In some embodiments, a work function barrier layer, such as barrier layer 62, is between WFM layer 56U′ and WFM layer 56L′. In some embodiments, metal fill/bulk layer 57 wraps a WFM layer of gate 60 (e.g., formed by WFM layer 56U′ and WFM layer 56L′). In some embodiments, gate 60 includes additional layers, such as a cap (e.g., a metal nitride cap and/or a silicon cap) and/or other gate layers.

Referring again to FIGS. 1A-1C, hard mask 58 includes a material that is different than subsequently formed insulation layers (e.g., of an interconnect structure) to provide etch selectivity. In some embodiments, hard mask 58 includes silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, hard mask 58 includes metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), other metal oxide, other metal nitride, or combinations thereof.

Device 10 may further include source/drain contacts (e.g., an upper source/drain contact 70U and a lower source/drain contact 70L), source/drain vias (e.g., a source/drain via 72), and gate vias (e.g., a gate via 74). Source/drain contact 70U is disposed on and electrically connected to at least one of source/drains 40U, source/drain contact 70L is disposed on and electrically connected to at least one of source/drains 40L, source/drain via 72 is disposed on an electrically connected to source/drain contact 70U, and gate via 74 is disposed on and electrically connected to gate 60. Source/drain contact 70U may be disposed in ILD layer 48U (FIG. 1C), and source/drain contact 70U may be disposed between gate spacers 30U (FIG. 1A). Source/drain contact 70L may be disposed in substrate 14 (FIG. 1A), and source/drain contact 70L may be disposed between substrate isolation structures 18 (FIG. 1C). Source/drain via 72 is disposed in an insulation layer 76, gate via 74 is disposed in insulation layer 76, and gate via 74 may extend through hard mask 58 to gate 60 (e.g., gate electrode 56U thereof). Source/drain contact 70U, source/drain contact 70L, source/drain via 72, and gate via 74 include electrically conductive material, which may include tungsten, ruthenium, cobalt, molybdenum, copper, aluminum, titanium, tantalum, iridium, palladium, platinum, nickel, tin, gold, silver, other suitable metal, alloys thereof, or combinations thereof. Insulation layer 76 includes electrically insulative material, such as a dielectric material, such as those described herein, and insulation layer 78 may have a multilayer structure (e.g., an ILD layer disposed over a CESL).

The present disclosure further recognizes that an electric field applied to gate 60, which is provided by applying a voltage to gate 60 via gate via 74, decreases as a distance from gate via 74 increases. For example, the electric field decreases from a top of gate 60 to a bottom of gate 60, as depicted by arrow EF, such that electric field strength may be highest at the top of gate 60 (i.e., closest to gate via 74) and lowest at the bottom of gate 60 (i.e., furthest away from gate via 74). An electric field applied to gate stack 60U (and thus gate electrode 56U) may thus be greater than an electric field applied to gate stack 60L, which may result in poor gate control of transistor 20L. Configuring gate electrode 56L with the gradient composition (e.g., with a top-light N/Ti ratio and a bottom-heavy N/Ti) may compensate for the lower electric field, for example, by increasing electrical conductivity of an upper portion of gate electrode 56L (e.g., by configuring the upper portion with a lower amount of nitrogen). In some embodiments, an amount and/or a concentration of nitrogen increases from top to bottom of gate electrode 56L, thereby reducing its overall resistance to voltage applied via gate via 74.

Stacked device structure 10 may further include a multilayer interconnect (MLI) structure disposed over insulation layer 76. The MLI structure may electrically connect devices (e.g., transistors, resistors, capacitors, inductors, etc.), components of devices (e.g., gates and/or source/drains), devices within the MLI structure, components of the MLI structure, or combinations thereof, such that the devices and/or components thereof may operate as specified by design requirements. The MLI structure may include metallization layers that route signals between the devices and/or the components thereof and/or distribute signals (e.g., clock signals, voltage signals, ground signals, other signals, or combinations thereof) to the devices and/or the components thereof. In some embodiments, a metallization layer/level includes at least one interconnect structure disposed in an insulation layer, such as a metal line and a via disposed in a dielectric layer (e.g., a CESL and an ILD layer), where the via electrically connects the metal line to a metal line of an interconnect in a different metallization layer.

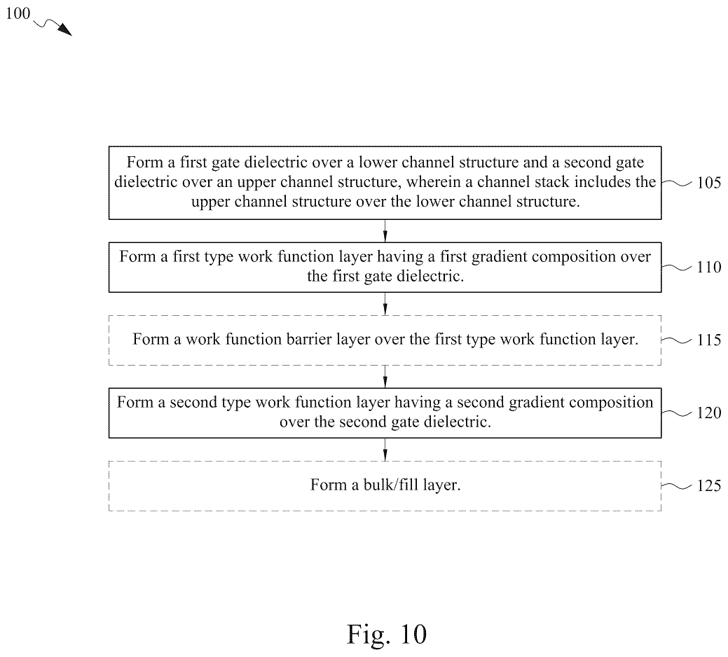

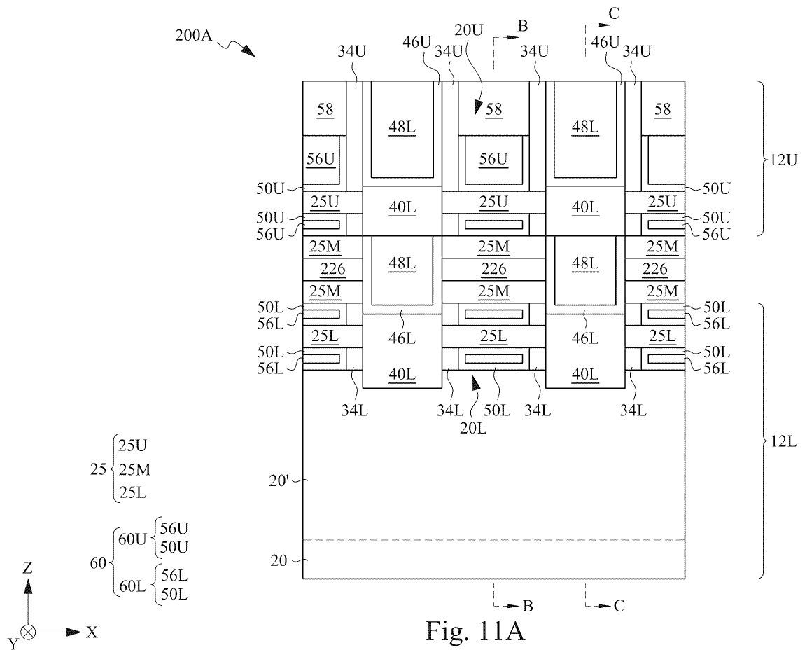

FIG. 10 is a flow chart of a method 100 for fabricating a gate stack of transistors of a transistor stack, such as gate 60 of the transistor stack of stacked device structure 10 of FIGS. 1A-IC, according to various aspects of the present disclosure. At block 105, method 100 includes forming a first gate dielectric (e.g., gate dielectric 50L) over a lower channel structure (e.g., semiconductor layers 25L) and a second gate dielectric (e.g., gate dielectric 50U) over an upper channel structure (e.g., semiconductor layers 25U). A channel stack may include the upper channel structure over the lower channel structure. At block 110, method 100 includes forming a first type work function layer having a first gradient composition (e.g., a PWFM layer (which may be or form a portion of gate electrode 56L), such as described above) over the first gate dielectric. At block 115, method 100 may include forming a work function barrier layer (e.g., barrier layer 62) over the first type work function layer. At block 120, method 100 includes forming a second type work function layer having a second gradient composition (e.g., an NWFM layer (which may be or form a portion of gate electrode 56U), such as described above) over the second gate dielectric. At block 125, method 100 may include forming a bulk/fill layer. The bulk/fill layer may be formed over the second type work function layer and/or the first type work function layer. FIG. 10 has been simplified for the sake of clarity to better understand the inventive concepts of the present disclosure. Additional steps may be provided before, during, and after method 100, and some of the steps described may be moved, replaced, or eliminated for additional embodiments of method 100.

In some embodiments, the first type work function layer is formed by depositing a first type work function material over the first gate dielectric and reducing a thickness of the first type work function material (e.g., by etching back the first type work function material). The first type work function material, as deposited, may be over the first gate dielectric, the lower channel structure, the second gate dielectric, and the upper channel structure. In some embodiments, the first type work function material may be removed from over the second gate dielectric and/or the upper channel structure, such as when the thickness of the first type work function material is reduced. In some embodiments, a flow rate of a non-metal-containing precursor (e.g., a nitrogen-containing precursor), a flow rate of a metal-containing precursor (e.g., a titanium-containing precursor), other deposition parameters, or combinations thereof are tuned to provide the first type work material with the first gradient composition. For example, a ratio of the flow rate of the non-metal-containing precursor to a flow rate of the metal-containing precursor is decreased as deposition time increases and/or a thickness of the first type work function material increases. In some embodiments, the first type work function layer is a titanium nitride layer, and a ratio of a flow rate of a nitrogen-containing precursor to a titanium-containing precursor may be varied during deposition (e.g., chemical vapor deposition (CVD)) of a titanium nitride material to provide the titanium nitride layer with a gradient N/Ti ratio. In some embodiments, an N/Ti flow rate ratio decreases as deposition time increases and/or a thickness of the titanium nitride material increases. In such embodiments, the N/Ti flow rate ratio may be at a maximum at a beginning of the deposition process (e.g., CVD) and at a minimum at the end of the deposition process. In some embodiments, the N/Ti flow rate ratio is decreased in a manner that provides the titanium nitride layer with a gradient N/Ti ratio that decreases from 0.8 to 0.4 from bottom to top, such as described herein.

In some embodiments, the second type work function layer is formed by depositing a second type work function material over the second gate dielectric and reducing a thickness of the second type work function material (e.g., by planarizing the second type work function material (e.g., by chemical mechanical planarization (CMP)). The second type work function material, as deposited, may be over the second gate dielectric, the upper channel structure, the first type work function layer, and device-level dielectric layer (e.g., ILD layer 48U and/or CESL 46U) and the second type work function material may be removed from over the device-level dielectric layer when reducing its thickness. In some embodiments, the first type work function layer may be formed over the second gate dielectric and/or the upper channel structure when formed over the first gate dielectric and/or the lower channel structure. In such embodiments, the first type work function layer is removed from over the second gate dielectric before forming the second type work function material. In some embodiments, a flow rate of a first metal-containing precursor (e.g., an aluminum-containing precursor), a flow rate of a second metal-containing precursor (e.g., a titanium-containing precursor), other deposition parameters, or combinations thereof are tuned to provide the second type work material with the second gradient composition. For example, a ratio of the flow rate of the first metal-containing precursor to a flow rate of the second metal-containing precursor is increased as deposition time increases and/or a thickness of the second type work function material increases. In some embodiments, the second type work function layer is a titanium aluminum layer, and a ratio of a flow rate of an aluminum-containing precursor to a titanium-containing precursor may be varied during deposition (e.g., CVD) of a titanium aluminum material to provide the titanium aluminum layer with a gradient Al/Ti ratio. In some embodiments, an Al/Ti flow rate ratio increases as deposition time increases and/or a thickness of the titanium aluminum material increases. In such embodiments, the Al/Ti flow rate ratio may be at a minimum at a beginning of the deposition process (e.g., CVD) and at a maximum at the end of the deposition process. In some embodiments, the Al/Ti flow rate ratio is increased in a manner that provides the titanium aluminum layer with a gradient Al/Ti ratio that increases from 0.4 to 0.8 from bottom to top, such as described herein.

In some embodiments, the first type work function layer (e.g., the PWFM layer) may not form in an entirely bottom-to-top manner. For example, the first type work function layer may form around the lower channel structure (e.g., semiconductor layers 25L) before filling a lower portion of a gate opening and/or before reaching its total thickness/height (e.g., between a top and a bottom thereof). In such example, a portion of the first type work function layer around semiconductor layers 25L may have a gradient N/Ti ratio. For example, an N/Ti ratio of the portion of the first type work function layer at gate dielectric 50L (e.g., high-k dielectric layer 54L thereof) may be 0.8, and the N/Ti ratio of the portion of the first type work function layer may decrease as distance from gate dielectric 50L increases. In other words, the first type work function layer may have gradient portions around semiconductor layers 25L, such as portions having gradient N/Ti ratios. In furtherance of such example, the N/Ti ratio in portions of the first type work function layer between semiconductor layer 25L may decrease and then increase along the gate height direction (e.g., the z-direction). For example, along the gate height direction (e.g., the z-direction), the N/Ti ratio may decrease from a first ratio (e.g., 0.8) at a portion of gate dielectric 50L over a bottom of top semiconductor layer 25L to a second ratio (e.g., less than 0.8 (e.g., 0.4)) at a point between top semiconductor layer 25L and middle semiconductor layer 25L (e.g., an equal distance from a bottom and top, respectively, thereof) and then increase from the second ratio to a third ratio (e.g., 0.8) at a portion of gate dielectric layer 50L over a top of middle semiconductor layer 25L. Accordingly, portions of the first type work function layer between the semiconductor/channel layers of the lower channel structure may have a middle portion sandwiched between an upper portion and a lower portion. The middle portion may have a first N/Ti ratio (e.g., a minimum N/Ti ratio), and the upper portion and the lower portion may have a second N/Ti ratio (e.g., a maximum N/Ti ratio) that is greater than the first N/Ti ratio. In some embodiments, a thickness of the middle portion may be greater than a thickness of the upper portion and a thickness of the lower portion.

In some embodiments, the second type work function layer (e.g., the NWFM layer) may not form in an entirely bottom-to-top manner. For example, the second type work function layer may form around the upper channel structure (e.g., semiconductor layers 25U) before filling an upper portion of the gate opening and/or before reaching its total thickness/height (e.g., between a top and a bottom thereof). In such example, a portion of the second type work function layer around semiconductor layers 25U may have a gradient Al/Ti ratio. For example, an Al/Ti ratio of the portion of the second type work function layer at gate dielectric 50U (e.g., high-k dielectric layer 54L thereof) may be 0.4, and the Al/Ti ratio of the portion of the second type work function layer may increase as distance from gate dielectric 50U increases. In other words, the second type work function layer may have gradient portions around semiconductor layers 25U, such as portions having gradient Al/Ti ratios. In furtherance of such example, the Al/Ti ratio in portions of the second type work function layer between semiconductor layer 25U may increase and then decrease along the gate height direction (e.g., the z-direction). For example, along the gate height direction (e.g., the z-direction), the Al/Ti ratio may increase from a first ratio (e.g., 0.4) at a portion of gate dielectric 50U over a bottom of top semiconductor layer 25U to a second ratio (e.g., greater than 0.4 (e.g., 0.8)) at a point between top semiconductor layer 25U and middle semiconductor layer 25U (e.g., an equal distance from a bottom and top, respectively, thereof) and then decrease from the second ratio to a third ratio (e.g., 0.4) at a portion of gate dielectric layer 50U over a top of middle semiconductor layer 25U. Accordingly, portions of the second type work function layer between the semiconductor/channel layers of the upper channel structure may have a middle portion sandwiched between an upper portion and a lower portion. The middle portion may have a first Al/Ti ratio (e.g., a maximum Al/Ti ratio), and the upper portion and the lower portion may have a second Al/Ti ratio (e.g., a minimum Al/Ti ratio) that is less than the second Al/Ti ratio. In some embodiments, a thickness of the middle portion may be greater than a thickness of the upper portion and a thickness of the lower portion.

In some embodiments, the work function barrier layer is formed by depositing a work function barrier material over the first type work function layer and reducing a thickness of the work function barrier material (e.g., by etching back the work function barrier material). The work function barrier material, as deposited, may be over the first type work function layer and the second gate dielectric, and the work function barrier material may be removed from over the second gate dielectric when reducing its thickness. In some embodiments, the first type work function layer, the work function barrier layer, and the second type work function layer are formed in, and may partially or fully, fill a gate opening. In some embodiments, the first gate dielectric and the second gate dielectric partially fill a gate opening. In some embodiments, the first gate dielectric partially fills spaces between lower channels of the lower channel structures, and the first type work function layer may partially or fully fill remainders of the spaces between the lower channels of the lower channel structures. In some embodiments, the second gate dielectric partially fills spaces between upper channels of the upper channel structures, and the second type work function layer may partially or fully fill remainders of the spaces between the upper channels of the upper channel structures. In some embodiments, the work function barrier layer partially fills a space between an upper channel of the upper channel structures and a lower channel of the lower channel structure. In some embodiments, the bulk/fill layer is formed by depositing a bulk/fill material over the second type work function layer and reducing a thickness of the bulk/fill material (e.g., (e.g., by planarizing the bulk/fill material (e.g., by CMP)). In some embodiments, the bulk/fill material layer fills a remainder of a gate opening.

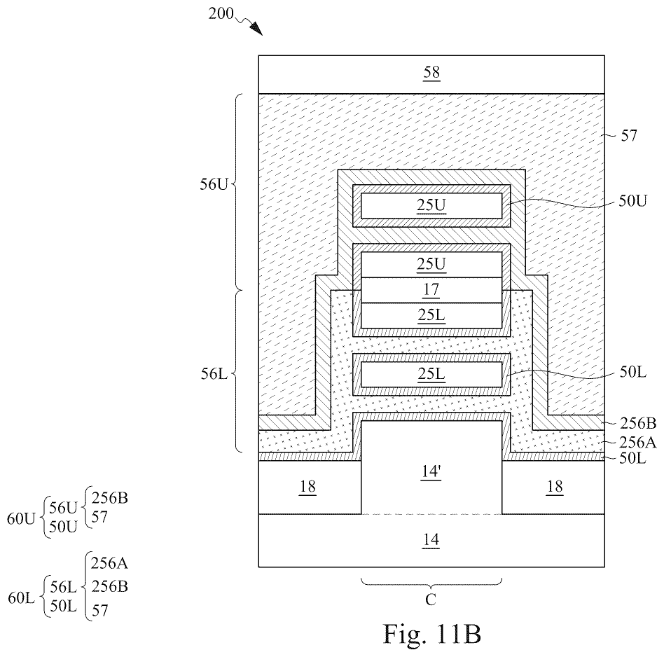

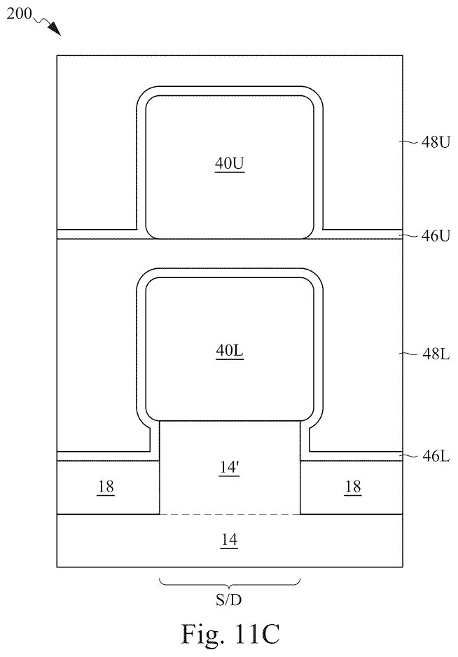

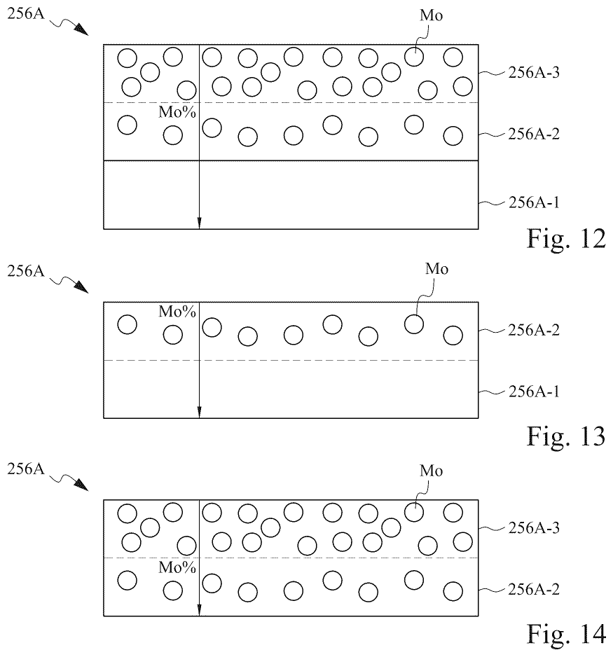

FIG. 11A is a cross-sectional view of a stacked device structure 200, in portion or entirety, according to various aspects of the present disclosure. FIG. 11B and FIG. 11C are cross-sectional views of stacked device structure 200, in portion or entirety, along line B-B and line C-C, respectively, of FIG. 11A according to various aspects of the present disclosure. Stacked device structure 200 is similar in many respects to stacked device structure 10. Accordingly, similar features of stacked device structure 200 in FIGS. 11A-11C and stacked device structure 10 in FIGS. 1A-1C are identified by the same reference numerals for clarity and simplicity. FIGS. 12-14 depict various configurations of a gate layer, in portion or entirety, which may be implemented in stacked device structure 200, according to various aspects of the present disclosure. FIGS. 11A-11C and FIGS. 12-14 have been simplified for the sake of clarity to better understand the inventive concepts of the present disclosure. Additional features may be added in stacked device structure 200, and some of the features described below may be replaced, modified, or eliminated in other embodiments of stacked device structure 200.

In FIGS. 11A-11C, transistor 20U and transistor 20L each include one channel layer (e.g., semiconductor layer 25U and semiconductor layer 25L, respectively), instead of three channel layers, and the present disclosure contemplates transistor 20U and transistor 20L include more channel layers than depicted in FIGS. 11A-11C. In stacked device structure 200, semiconductor layers 25M are disposed between semiconductor layer 25U and semiconductor layer 25L, and semiconductor layers 25M (also referred to as dummy channel layers and/or dummy channels) extend between respective source/drain isolation structures (e.g., ILD layer 48L and/or CESL 46L). Semiconductor layers 25M include semiconductor material, such as those described herein (e.g., silicon, silicon germanium, or germanium), and a composition of semiconductor layers 25M may be the same or different than compositions of semiconductor layer 25U and/or semiconductor layer 25L. In some embodiments, semiconductor layer 25U and semiconductor layer 25M in device region 12U include the same semiconductor material, and semiconductor layer 25L and semiconductor layer 25M in device region 12L include the same semiconductor material. Semiconductor layer 25U, semiconductor layers 25M, and semiconductor layer 25L may also collectively be referred to as semiconductor layers 25.

Stacked device structure 200 further includes an insulation structure 226 disposed between semiconductor layers 25M. Insulation structure 226 may extend between respective source/drain isolation structures (e.g., ILD layer 48L and/or CESL 46L). In some embodiments, source/drain isolation structures may electrically isolate source/drain regions from one another (e.g., source/drains 40U and source/drains 40L), and/or insulation structure 226 may electrically isolate channel regions from one another (e.g., semiconductor layer 25U and semiconductor layer 25L). In such embodiments, insulation structure 226 may be referred to as a channel isolation structure. Insulation structure 226 includes an electrically insulating material(s). For example, insulation structure 226 may include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). Insulation structure 226 may include a single insulation layer or multiple insulation layers.

Further, transistor 20U includes gate stack 60U, which includes gate dielectric 50U and gate electrode 56U, and transistor 20L includes gate stack 60L, which includes gate dielectric 50L and gate electrode 56L. In stacked semiconductor structure 200, gate electrode 56L includes a PWFM layer 256A, an NWFM layer 256B, and a bulk/fill layer 258, and gate electrode 56U includes NWFM layer 256B and bulk layer 258. NWFM layer 256B is formed of n-type work function metal material, which may include aluminum, titanium, tantalum, zirconium, other n-metal, alloys thereof, or combinations thereof. For example, NWFM layer 256B may be a titanium aluminum layer, a titanium aluminum carbide layer, a tantalum layer, a tantalum aluminum layer, a tantalum aluminum carbide layer, or combinations thereof. In the depicted embodiment, NWFM layer 256B is a titanium aluminum carbide layer. NWFM layer 256B may have a gradient composition or a uniform/constant composition. For example, an Al/Ti ratio in NWFM layer 256B may be uniform along its thickness (e.g., the Al/Ti ratio may be substantially the same from a top of NWFM layer 256B (which may abut/interface with bulk layer 258) to a bottom of NWFM layer 256B (which may abut/interface with PWFM layer 256A). In another example, an Al/Ti ratio in NWFM layer 256B may be gradient along its thickness (e.g., the Al/Ti ratio may decrease from a top thereof to a bottom thereof), which may reduce diffusion of aluminum from NWFM layer 256B into PWFM layer 256A as described herein. In some embodiments, NWFM layer 256B has a multilayer structure.

PWFM layer 256A is formed of p-type work function metal material, which may include titanium, tantalum, ruthenium, molybdenum, tungsten, palladium, platinum, iridium, other p-metal, alloys thereof, or combinations thereof. In the depicted embodiment, PWFM layer 256A is a titanium nitride layer that is doped with a constituent that can inhibit constituents of NWFM layer 256B (e.g., aluminum) from diffusing into PWFM layer 256A. For example, PWFM layer 256A includes an aluminum-blocking constituent, such as tungsten and/or molybdenum, and the aluminum-blocking constituent reduces and/or prevents diffusion of aluminum from NWFM layer 256B into PWFM layer 256A. In some embodiments, PWFM layer 256A is a molybdenum-doped titanium nitride layer, a tungsten-doped titanium nitride layer, or a molybdenum-and-tungsten doped titanium nitride layer.

To further enhance its diffusion blocking capabilities and provide threshold voltage tunability (e.g., by obtaining different p-type work function characteristics), an amount of the aluminum-blocking constituent is greatest at the DWFM layer interface, such as in a portion of PWFM layer 256A that abuts NWFM layer 256B. In some embodiments, an amount of the aluminum-blocking constituent decreases along a thickness of PWFM layer 256A from a top to a bottom thereof. For example, a concentration of the aluminum-blocking constituent in PWFM layer 256A decreases from a top thereof (which abuts/interfaces with NWFM layer 256B) to a bottom thereof (which may abut/interface with gate dielectric 50L). In such example, a maximum concentration of the aluminum-blocking constituent is in a portion of the PWFM layer 256A abutting NWFM layer 256B, and a minimum concentration of the aluminum-blocking constituent (which may be effectively zero) is in a portion of the PWFM layer 256A abutting gate dielectric 50L (e.g., high-k dielectric layer 54L thereof). In some embodiments, the concentration of the aluminum-blocking constituent in PWFM layer 256A is gradient (e.g., increasing or decreasing along thickness). In some embodiments, the concentration of the aluminum-blocking constituent in PWFM layer 256A is banded. For example, the PWFM layer 256A may have a top portion (or band) with a first concentration of the aluminum-blocking constituent, a middle portion with a second concentration of the aluminum-blocking constituent, and a bottom portion with a third concentration of the aluminum-blocking constituent. In such example, the second concentration may be less than the first concentration and greater than the third concentration, such that the concentration of the aluminum-blocking constituent decrease from top to bottom.

In some embodiments, since PWFM layer 256A forms around the lower channel structure (and may have sublayers as described below), a concentration profile of the aluminum-blocking constituent of portions of PWFM layer 256A along sidewalls of the lower channel structure (e.g., along sidewalls of the semiconductor (channel) layers thereof) may be different than portions of PWFM layer 256A between tops/bottoms of the lower channel structure (e.g., between tops/bottoms of the semiconductor (channel) layers thereof). For example, a concentration of the aluminum-blocking constituent in portions of PWFM layer 256A along sidewalls of semiconductor layer 25L and semiconductor layer 25M may increase along the gate lengthwise direction (e.g., the y-direction) from gate dielectric 50L (e.g., high-k dielectric layer 54L thereof) thereover to NWFM layer 256B, such that a maximum concentration of the aluminum-blocking constituent is in sidewall portions of PWFM layer 256A that abut NWFM layer 256B and a minimum concentration of the aluminum-blocking constituent is in the sidewall portions of PWFM layer 256A that abut portions of gate dielectric 50L (e.g., high-k dielectric layer 54L thereof) over sidewalls of semiconductor layer 25L/semiconductor layer 25M. In contrast, a concentration of the aluminum-blocking constituent in a portion of the PWFM layer 256A between semiconductor layer 25M and semiconductor layer 25L may increase and then decrease along the gate height direction (e.g., the z-direction) from a portion of gate dielectric 50L (e.g., high-k dielectric layer 54L thereof) over a bottom of semiconductor layer 25M to a portion of gate dielectric layer 50L (e.g., high-k dielectric layer 54L thereof) over a top of semiconductor layer 25L. For example, along the gate height direction (e.g., the z-direction), the concentration of the aluminum-blocking constituent increases from a first concentration at a portion of gate dielectric 50L over a bottom of semiconductor layer 25M to a second concentration (e.g., a maximum concentration) at a point between semiconductor layer 25M and semiconductor layer 25L (e.g., an equal distance from a bottom and top, respectively, thereof) and then decreases from the second concentration to a third concentration at a portion of gate dielectric layer 50L over a top of semiconductor layer 25L. The first concentration and the third concentration may be the same. In a similar manner, a concentration of the aluminum-blocking constituent in a portion of PWFM layer 256A between semiconductor layer 25L and substrate 14 may increase and then decrease along the gate height direction (e.g., the z-direction) from a portion of gate dielectric 50L (e.g., high-k dielectric layer 54L thereof) over a bottom of semiconductor layer 25L to a portion of gate dielectric layer 50L (e.g., high-k dielectric layer 54L thereof) over substrate 14. Accordingly, portions of PWFM layer 256A between the semiconductor/channel layers of the lower channel structure may have a middle portion sandwiched between an upper portion and a lower portion. The middle portion may have a first concentration (e.g., a maximum concentration) of the aluminum-blocking constituent, and the upper portion and the lower portion may have a second concentration (e.g., a minimum concentration) of the aluminum-blocking constituent that is less than the first concentration. In some embodiments, a thickness of the middle portion is greater than a thickness of the upper portion and a thickness of the lower portion.

The varied concentration of the aluminum-blocking constituent may be provided by forming PWFM layer 256A by atomic layer deposition (ALD), instead of CVD, such that PWFM layer 256A is formed of at least two sublayers and at least a top one of the at least two sublayers include the aluminum-blocking constituent. In the depicted embodiment, PWFM layer 256A is a molybdenum-doped titanium nitride layer, and FIG. 12 provides a configuration of a molybdenum-doped titanium nitride layer that may be provided by ALD and contain desired aluminum-blocking capabilities (e.g., a maximum concentration of aluminum in a portion of PWFM layer 256A that abuts NWFM layer 256B, which may be a top portion or a bottom portion of PWFM layer 256A depending on transistor stack configuration). Referring to FIG. 12, PWFM layer 256A includes a titanium nitride (TiN) sublayer 256A-1 formed by a respective ALD cycle, a molybdenum-doped titanium nitride (TiMoN) sublayer 256A-2 formed by a respective ALD cycle, and a molybdenum nitride (MoN) sublayer 256A-3 formed by a respective ALD cycle. In such example, a concentration of molybdenum (Mo %) decreases from a top of PWFM layer 256A (formed by MON sublayer 256A-3) to a bottom of PWFM layer 256A (formed by TiN sublayer 256A-1). For example, Mo % in MON sublayer 256A-3 is greater than Mo % in TiMoN sublayer 256A-2, which is greater than Mo % in TiN sublayer 256A-1.

The present disclosure contemplates PWFM layer 256A having more or less sublayers. Referring to FIG. 13, PWFM layer 256A includes two sublayers, instead of three, such as TIN sublayer 256A-1 formed by a respective ALD cycle and TiMoN sublayer 256A-2 formed by a respective ALD cycle. In such example, Mo % decreases from a top of PWFM layer 256A (formed by TiMoN sublayer 256A-2) to a bottom of PWFM layer 256A (formed by TiN sublayer 256A-1). For example, Mo % in TiMoN sublayer 256A-2 is greater than Mo % in TiN sublayer 256A-1. Referring to FIG. 14, PWFM layer 256A includes two sublayers, such as TiMoN sublayer 256A-2 formed by a respective ALD cycle and MON sublayer 256A-3 formed by a respective ALD cycle. In such example, Mo % decreases from a top of PWFM layer 256A (formed by MoN sublayer 256A-3) to a bottom of PWFM layer 256A (formed by TiMoN sublayer 256A-2). For example, Mo % in MON sublayer 256A-1 is greater than Mo % in TiMoN sublayer 256A-2. Various other sublayer configurations are contemplated, and the configuration of PWFM layer 256A may be adjusted depending on desired aluminum-blocking ability, which may be determined based on an aluminum concentration (Al %) of NWFM layer 256B. For example, when NWFM layer 256B has a high aluminum concentration, PWFM layer 256A may be configured as depicted in FIG. 14 (i.e., omit TiN sublayer 256A-1) to increase its ability to block aluminum diffusion, and PWFM layer 256A may be configured as depicted in FIG. 13 (i.e., omit MON sublayer 256A-3) when less robust aluminum diffusion blocking ability is needed, such as when NWFM layer 256B has a lower aluminum concentration.

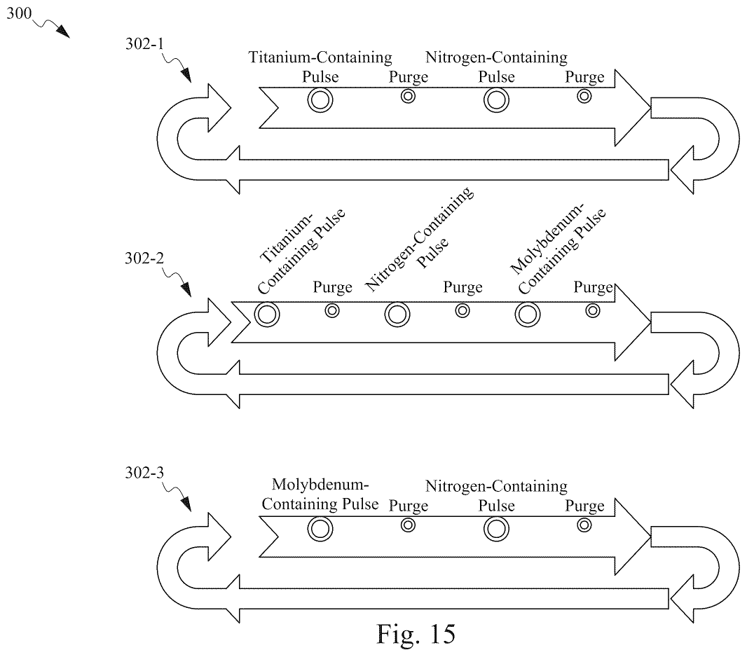

Mo % distribution in PWFM layer 256A, such as that depicted in FIGS. 12-14, is controlled by ALD. FIG. 15 is a flow chart of an exemplary ALD process 300, which may be implemented to form and provide PWFM layer 256A with desired Mo % variations, according to various aspects of the present disclosure. ALD process 300 includes a TIN ALD cycle 302-1, a TiMoN ALD cycle 302-2, and a MON ALD cycle 302-3, and PWFM layer 256A is formed by performing at least two cycles of ALD process 300. For example, PWFM layer 256A as depicted in FIG. 12 may be formed by performing all three ALD cycles-TIN ALD cycle 302-1, followed by TiMoN ALD cycle 302-2, followed by MON ALD cycle 302-3. In another example, PWFM layer 256A as depicted in FIG. 13 may be formed by performing two of the three ALD cycles-TIN ALD cycle 302-1 followed by TiMoN ALD cycle 302-2. In yet another example, PWFM layer 256A as depicted in FIG. 14 may be formed by performing two of the three ALD cycles-TiMoN ALD cycle 302-2 followed by MON ALD cycle 302-3. FIG. 15 has been simplified for the sake of clarity to better understand the inventive concepts of the present disclosure. Additional steps may be provided before, during, and after ALD process 300 (and/or cycles thereof), and some of the steps described may be moved, replaced, or eliminated for additional embodiments of ALD process 300 (and/or cycles thereof).

ALD process 300 includes loading stacked device structure 200 into a process chamber, where the process chamber is prepared for an ALD process to form a PWFM layer, such as PWFM layer 256A. TIN ALD cycle 302-1 includes a titanium-containing pulse (which may include flowing a titanium-containing precursor into the process chamber and thus exposing stacked device structure 200 thereto), a purge process to remove any remaining titanium-containing precursor and any byproducts from the process chamber, a nitrogen-containing pulse (which may include flowing a nitrogen-containing precursor into the process chamber and thus exposing stacked device structure 200 thereto), and a purge process to remove any remaining nitrogen-containing precursor and any byproducts from the process chamber. The two deposition phases (titanium-containing pulse and nitrogen-containing pulse) and two purge phases may constitute a TIN ALD subcycle, and the TIN ALD subcycle is a self-limiting process, where less than or equal to about one titanium-and-nitrogen comprising monolayer may be deposited during a given TiN ALD subcycle. TIN ALD cycle 302-1 thus repeats the TIN ALD subcycle until a TiN sublayer, such as TiN sublayer 256A-1, reaches a desired (target) thickness. For example, if a thickness of a TiN sublayer equals a target thickness (or is within a given threshold of the target thickness), then TIN ALD cycle 302-1 ends. If the thickness of the TiN sublayer does not equal the target thickness (or is not within the given threshold of the target thickness), then TIN ALD cycle 302-1 begins another TIN ALD subcycle.

TiMoN ALD cycle 302-2 includes a titanium-containing pulse (which may include flowing a titanium-containing precursor into the process chamber and thus exposing stacked device structure 200 thereto), a purge process to remove any remaining titanium-containing precursor and any byproducts from the process chamber, a nitrogen-containing pulse (which may include flowing a nitrogen-containing precursor into the process chamber and thus exposing stacked device structure 200 thereto), a purge process to remove any remaining nitrogen-containing precursor and any byproducts from the process chamber, a molybdenum-containing pulse (which may include flowing a molybdenum-containing precursor into the process chamber and thus exposing stacked device structure 200 thereto), and a purge process to remove any remaining molybdenum-containing precursor and any byproducts from the process chamber. The three deposition phases (titanium-containing pulse, nitrogen-containing pulse, and molybdenum-containing pulse) and three purge phases may constitute a TiMoN ALD subcycle, and the TiMoN ALD subcycle is a self-limiting process, where less than or equal to about one titanium-nitrogen-and-molybdenum comprising monolayer may be deposited during a given TiMoN ALD subcycle. TiMoN ALD cycle 302-2 thus repeats the TiMoN ALD subcycle until a TiMoN sublayer, such as TiMoN sublayer 256A-2, reaches a desired (target) thickness. For example, if a thickness of a TiMoN sublayer equals a target thickness (or is within a given threshold of the target thickness), then TiMoN ALD cycle 302-2 ends. If the thickness of the TiMoN sublayer does not equal the target thickness (or is not within the given threshold of the target thickness), then TiMoN ALD cycle 302-2 begins another TiMoN ALD subcycle.

MON ALD cycle 302-3 includes a molybdenum-containing pulse (which may include flowing a molybdenum-containing precursor into the process chamber and thus exposing stacked device structure 200 thereto), a purge process to remove any remaining molybdenum-containing precursor and any byproducts from the process chamber, a nitrogen-containing pulse (which may include flowing a nitrogen-containing precursor into the process chamber and thus exposing stacked device structure 200 thereto), and a purge process to remove any remaining nitrogen-containing precursor and any byproducts from the process chamber. The two deposition phases (molybdenum-containing pulse and nitrogen-containing pulse) and two purge phases may constitute a MoN ALD subcycle, and the MON ALD subcycle is a self-limiting process, where less than or equal to about one molybdenum-and-nitrogen comprising monolayer may be deposited during a given MON ALD subcycle. MON ALD cycle 302-3 thus repeats the MON ALD subcycle until a MON sublayer, such as TiMoN sublayer 256A-3, reaches a desired (target) thickness. For example, if a thickness of a MON sublayer equals a target thickness (or is within a given threshold of the target thickness), then MON ALD cycle 302-3 ends. If the thickness of the MoN sublayer does not equal the target thickness (or is not within the given threshold of the target thickness), then MON ALD cycle 302-3 begins another MON ALD subcycle.

In some embodiments, the titanium-containing precursor is titanium tetrachloride (TiCl₄). In some embodiments, the nitrogen-containing precursor is ammonia (NH₃). In some embodiments, the molybdenum-containing precursor is molybdenum (V) chloride (MoCl₅). The present disclosure contemplates other titanium-containing precursors, nitrogen-containing precursors, and molybdenum-containing precursors. In some embodiments, a carrier gas is used to deliver the titanium-containing precursor, the nitrogen-containing precursor, or the molybdenum-containing precursor to the process chamber. The carrier gas may be an inert gas, such as an argon-containing gas, a helium-containing gas, other suitable inert gas, or combinations thereof. Various parameters of ALD process 300 may be tuned to achieve desired Mo %, such as a flow rate of a deposition gas (e.g., a flow rate of a titanium-containing precursor gas, a nitrogen-containing precursor gas, a molybdenum-containing precursor gas, a carrier gas, or combinations thereof), a concentration (or dosage) of the titanium-containing precursor gas, a concentration (or dosage) of the nitrogen-containing precursor gas, a concentration (or dosage) of the molybdenum-containing precursor gas, a concentration (or dosage) of the carrier gas, a pressure maintained in the process chamber, a duration of the deposition process (e.g., an ALD cycle), a deposition temperature, other suitable deposition parameters, or combinations thereof. In some embodiments, a purge process implements an inert gas, such as an argon-containing gas, a helium-containing gas, other suitable inert gas, or combinations thereof.

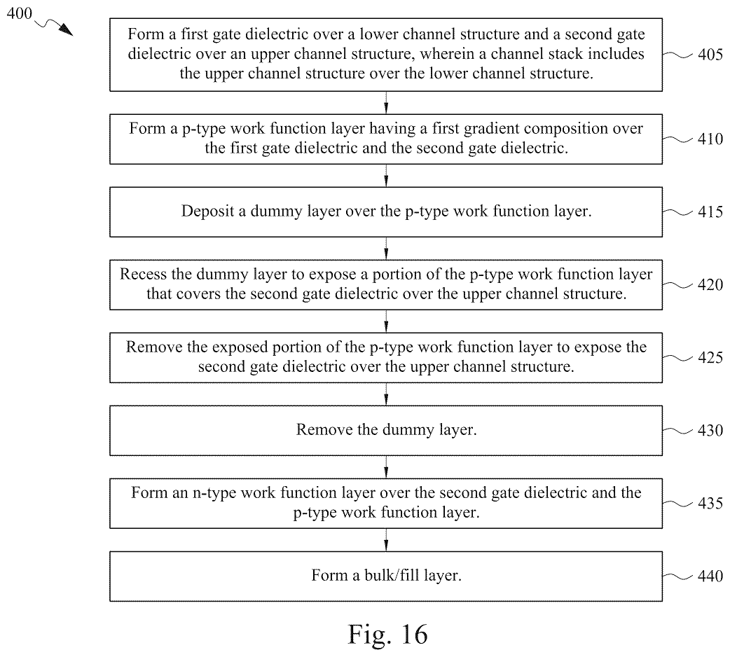

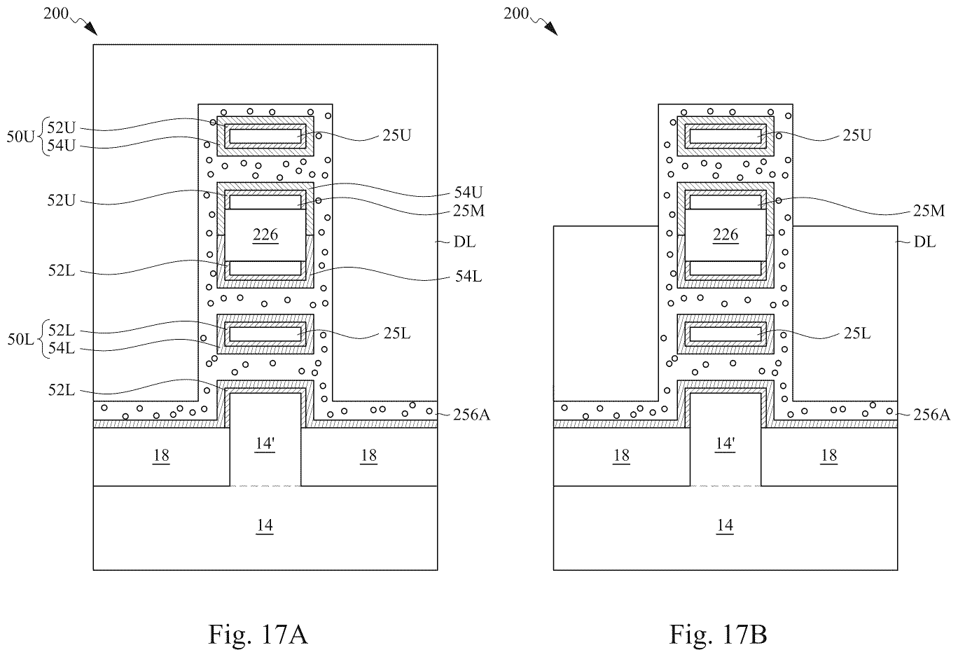

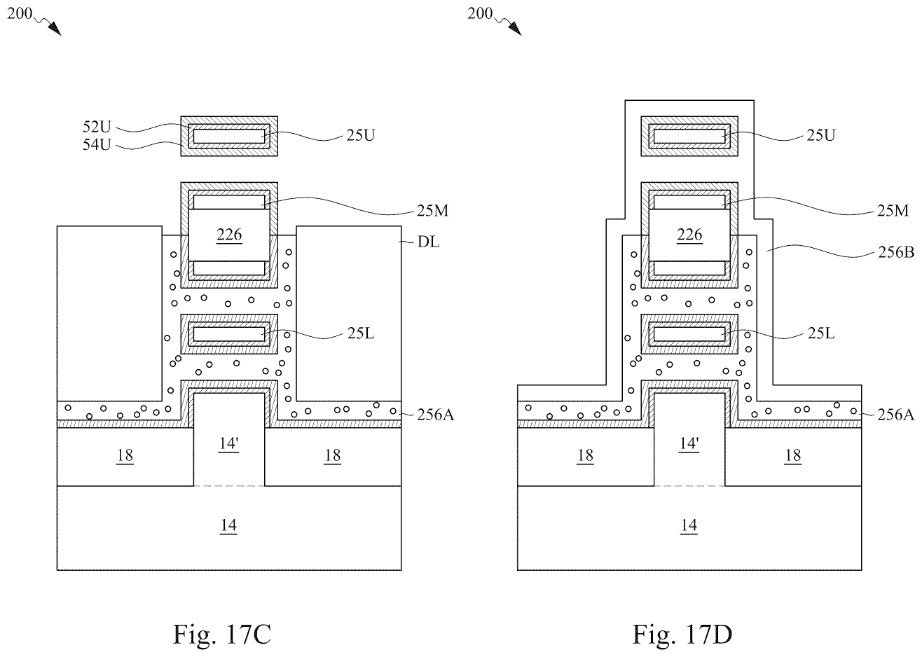

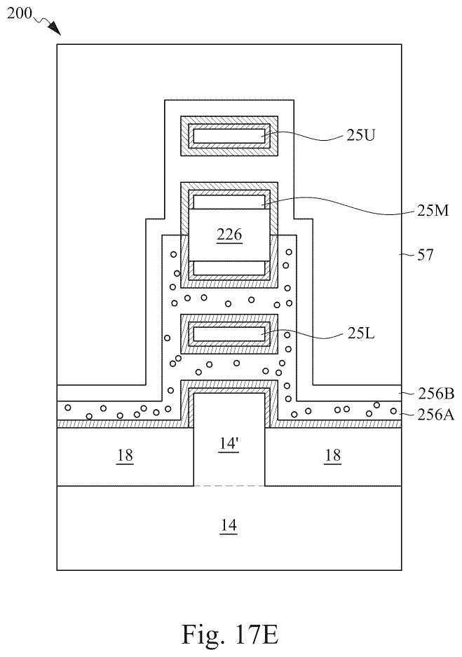

FIG. 16 is a flow chart of a method 400 for fabricating a gate stack of transistors of a transistor stack, such as gate 60 of the transistor stack of stacked device structure 200 of FIGS. 11A-11C, according to various aspects of the present disclosure. FIGS. 17A-17E are cross-sectional views of a stacked device structure, such as stacked device structure 200, in portion or entirety, at various fabrication stages associated with method 400 of FIG. 16 according to various aspects of the present disclosure. Method 400 described with reference to FIGS. 17A-17E may provide stacked device structure 200 with an improved DWFM gate, such as described herein. The cross-sectional views of FIGS. 17A-17E are taken (cut) along a gate lengthwise direction (e.g., a y-direction), like the cross-sectional view of FIG. 11B. FIG. 16 and FIGS. 17A-17E have been simplified for the sake of clarity to better understand the inventive concepts of the present disclosure. Additional steps may be provided before, during, and after method 400, and some of the steps described may be moved, replaced, or eliminated for additional embodiments of method 400. Additional features may be added in stacked device structure 200 depicted in FIGS. 17A-17E, and some of the features described below can be replaced, modified, or eliminated in other embodiments of stacked device structure 200.

Referring to FIG. 16 and FIG. 17A, method 400 at block 405 includes forming a first gate dielectric (e.g., gate dielectric 50L) over a lower channel structure (e.g., semiconductor layer 25L) and a second gate dielectric (e.g., gate dielectric 50U) over an upper channel structure (e.g., semiconductor layer 25U). A channel stack may include the upper channel structure over the lower channel structure. In some embodiments, such as depicted in FIG. 17A, the first gate dielectric (e.g., gate dielectric 50L) may be formed over mesas 14′ and/or substrate isolation structure 18 (e.g., STIs). In some embodiments, such as depicted in FIG. 17A, the first gate dielectric (e.g., gate dielectric 50L) may be formed over respective semiconductor layers 25M (e.g., those in device region 12L), and the second gate dielectric (e.g., gate dielectric 50U) may be formed over respective semiconductor layers 25M (e.g., those in device region 12U). In some embodiments, such as depicted in FIG. 17A, the first gate dielectric (e.g., high-k dielectric layer 54L of gate dielectric 50L) and/or the second gate dielectric (e.g., high-k dielectric layer 54U gate dielectric 50U) may be formed over insulation structure 226.

Referring to FIG. 16 and FIG. 17A, method 400 at block 410 includes forming a p-type work function layer, such as PWFM layer 256A, over the first gate dielectric (e.g., gate dielectric 50L) and the second gate dielectric (e.g., gate dielectric 50U). PWFM layer 256A is configured and formed as described above with reference to FIGS. 11A-11C and FIGS. 12-15. For example, in the depicted embodiment, PWFM layer 256A is a molybdenum-doped titanium nitride layer, which is formed by ALD, such as ALD process 300, and PWFM layer 256A has a greatest concentration of molybdenum at a top thereof. In some embodiments, the concentration of molybdenum in PWFM layer 256A is graded and/or banded, as described herein. In some embodiments, PWFM layer 256A is a tungsten-doped titanium nitride layer, which is formed by ALD, such as ALD process 300 (where tungsten may be substituted for molybdenum in the description thereof), and PWFM layer 256A has a greatest concentration of tungsten at a top thereof. In some embodiments, the concentration of tungsten in PWFM layer 256A is graded and/or banded, as described herein. Molybdenum and/or tungsten may reduce diffusion of aluminum from a subsequently formed n-type work function layer into PWFM layer 256A.

Referring to FIG. 16, FIG. 17A, and FIG. 17B, method 400 includes forming a dummy layer DL over the p-type work function layer (e.g., PWFM layer 256A). For example, method 400 includes depositing a dummy layer (e.g., dummy layer DL) over the p-type work function layer (e.g., PWFM layer 256A) at block 415 (FIG. 17A) and recessing the dummy layer (e.g., dummy layer DL) to expose a portion of the p-type work function layer (e.g., PWFM layer 256A) that covers the second gate dielectric (e.g., gate dielectric 50U) over the upper channel structure (e.g., semiconductor layer 25U) (FIG. 17B). In FIG. 17B, dummy layer DL covers the lower channel structure (e.g., semiconductor layer 25L) of the channel stack. That is, dummy layer DL covers PWFM layer 256A around the lower channel structure (e.g., semiconductor layer 25L) but leaves PWFM layer 256A around the upper channel structure (e.g., semiconductor layer 25U) exposed for subsequent processing. A composition of dummy layer DL is different than a composition of PWFM layer 256A and a subsequently formed n-type work function layer (e.g., NWFM layer 256B) to enable selective removal/etching therebetween. In some embodiments, dummy layer DL is a dielectric material that includes silicon and oxygen and/or carbon. For example, dummy layer DL is a silicon oxide layer (e.g., an SiO layer) and/or a silicon oxycarbide layer (e.g., an SiOC layer). In some embodiments, dummy layer DL is a bottom antireflective coating (BARC), which may include silicon and oxygen and/or carbon. In some embodiments, dummy layer DL is formed by a spin-on deposition process and/or other deposition process (e.g., CVD). In some embodiments, dummy layer DL is recessed by an etching process (e.g., an etch back, such as a BARC etch back).

Referring to FIG. 16 and FIG. 17C, method 400 at block 425 includes removing the exposed portion of the p-type work function layer (e.g., PWFM layer 256A) to expose the second gate dielectric (e.g., gate dielectric 50U) over the upper channel structure (e.g., semiconductor layer 25U). In some embodiments, an etching process selectively removes PWFM layer 256A with respect to dummy layer DL and gate dielectric 50U (e.g., high-k dielectric layer 54U thereof). For example, the etching process etches PWFM layer 256A with no (or negligible) etching of dummy layer DL and high-k dielectric layer 54U. An etchant of the etching process may etch PWFM layer 256A (e.g., a metal material) at a higher rate than dummy layer DL (e.g., a dielectric material) and high-k dielectric layer 54U (e.g., another dielectric material). The etching process is a dry etch, a wet etch, other suitable etch, or combinations thereof.

Referring to FIG. 16 and FIG. 17D, method 100 at block 430 includes removing the dummy layer (e.g., dummy layer DL). In some embodiments, an etching process selectively removes dummy layer DL with respect to PWFM layer 256A and gate dielectric 50U (e.g., high-k dielectric layer 54U thereof). For example, the etching process etches dummy layer DL with no (or negligible) etching of PWFM layer 256A and high-k dielectric layer 54U. An etchant of the etching process may etch dummy layer DL (e.g., dielectric material having a first composition (e.g., silicon oxide or silicon oxycarbide)) at a higher rate than PWFM layer 256A (e.g., metal material) and high-k dielectric layer 54U (e.g., dielectric material having a second composition (e.g., hafnium oxide) that is different than the first composition). The etching process is a dry etch, a wet etch, other suitable etch, or combinations thereof.

Referring to FIG. 16 and FIG. 17D, method 100 at block 435 includes forming an n-type work function layer (e.g., NWFM layer 256B) over the second gate dielectric (e.g., gate dielectric 50U) and the p-type work function layer (e.g., PWFM layer 256A). NWFM layer 256B may be configured (e.g., with a constant composition or a gradient composition) and formed (e.g., by CVD) as described herein. In the depicted embodiment, NWFM layer 256B is a titanium aluminum carbide layer, and NWFM layer 256B is formed directly on PWFM layer 256A. As described herein, because PWFM layer 256A is doped with molybdenum (and/or tungsten) and a concentration of thereof may be varied by the disclosed ALD process, PWFM layer 256A may function as both a tunable work function layer and a tunable aluminum barrier layer, such that no work function barrier layer is needed between PWFM layer 256A and NWFM layer 256B. PWFM layer 256A may thus simplify processing complexity and/or cost.

Referring to FIG. 16 and FIG. 17E, method 100 at block 440 includes forming a bulk/fill layer (e.g., bulk/fill layer 57). Bulk/fill layer 57 may be formed over NWFM layer 256B and/or PWFM layer 256A. In some embodiments, forming bulk/fill layer 57 includes depositing an electrically conductive material over NWFM layer 256B by ALD, CVD, physical vapor deposition (PVD), plating, other suitable process, or combinations thereof. The electrically conductive material may fill a remainder of a gate opening. In some embodiments, a planarization process (e.g., CMP) may be performed to remove excess electrically conductive material, such as that disposed over ILD layer 48U and/or CESL 46U.

In view of the present disclosure, stacked device structures, such as stacked device structure 10 and stacked device structure 200, may provide a CFET having a first transistor (e.g., transistor 20U, such as an n-type transistor) over a second transistor (e.g., transistor 20L, such as a p-type transistor), and gate electrodes of the first transistor and the second transistor include different type work function materials that are configured to improve device performance. For example, the first transistor may include an NWFM layer as described herein, the second GAA transistor may include a PWFM layer as described herein. The first transistor may have a first threshold voltage, and the second transistor may have a second threshold voltage. In some embodiments, the NWFM layer and the PWFM layer are configured with gradient compositions as described above with references to FIGS. 1A-1C and FIGS. 2-10, which may reduce variations in the first threshold voltage and the second threshold voltage. In some embodiments, the PWFM layer is doped with molybdenum and/or tungsten as described above with references to FIGS. 11A-11C, FIGS. 12-15, and FIGS. 17A-17C, which may also reduce variations in the first threshold voltage and the second threshold voltage. When the disclosed CFETs are implemented in memory applications (e.g., in static random-access memory (SRAM)), the reduction in aluminum provided by the disclosed DWFM gate configurations may reduce threshold voltage variations observed in the CFETs by about 10% to about 15%, reduce minimum power supply voltages (V_{ccmin}) (e.g., by as much as 30 mV to 60 mV), improve overall performance, or combinations thereof. Different embodiments may have different advantages, and no particular advantage is required of any embodiment.

Stacked device structure 10, stacked device structure 200, transistor 20U, transistor 20L, etc. may be included in a microprocessor, a memory, other device, or combinations thereof. In some embodiments, stacked device structure 10 and/or stacked device structure 200 described herein is a portion of an IC chip, a system on chip (SoC), or portion thereof, that includes various passive and active microelectronic devices, such as resistors, capacitors, inductors, diodes, p-type FETs (PFETs), n-type FETs (NFETs), metal-oxide semiconductor FETs (MOSFETs), complementary metal-oxide semiconductor (CMOS) transistors, bipolar junction transistors (BJTs), laterally diffused MOS (LDMOS) transistors, high voltage transistors, high frequency transistors, other components, or combinations thereof.

The present disclosure provides for many different embodiments. Gate stack (e.g., high-k/metal gate) fabrication methods are described herein and provide numerous advantages, particularly for stacked device structures. The gate stacks disclosed herein may be implemented in a variety of device types. For example, the gate stacks described herein are suitable for stacked planar field-effect transistors (FETs), stacked multigate transistors, such as stacked FinFETs, stacked GAA transistors, stacked fork-sheet devices, stacked omega-gate (Ω-gate) devices, stacked pi-gate (Π-gate) devices, or combinations thereof.

An exemplary stacked device structure includes a gate and a semiconductor layer stack. The semiconductor layer stack is disposed over a substrate, and the semiconductor layer stack includes a first semiconductor layer disposed over a second semiconductor layer. The gate includes a first gate dielectric layer and a second gate dielectric layer. The first gate dielectric layer is disposed over the first semiconductor layer, and the second gate dielectric layer is disposed over the second semiconductor layer. The gate further includes a first type work function metal layer and a second type work function metal layer. The first type work function metal layer is disposed over the first gate dielectric layer, and the second type work function metal layer is disposed over the second gate dielectric layer. At least one of the first type work function metal layer or the second type work function metal layer has a gradient composition.

In some embodiments, the first type work function metal layer is disposed around the first semiconductor layer, and the second type work function metal layer is disposed around the second semiconductor layer. In some embodiments, the second type work function metal layer has the gradient composition, the second type work function metal layer includes nitrogen and titanium, and a ratio of the nitrogen to the titanium increases from a top of the second type work function metal layer to a bottom of the second type work function metal layer. In some embodiments, the first type work function metal layer has the gradient composition, the first type work function metal layer includes nitrogen and titanium, and a ratio of the nitrogen to the titanium decreases from a top of the first type work function metal layer to a bottom of the first type work function metal layer. In some embodiments, the first type work function metal layer has the gradient composition, the first type work function metal layer includes aluminum and titanium, and a ratio of the aluminum to the titanium decreases from a top of the first type work function metal layer to a bottom of the first type work function metal layer. In some embodiments, the second type work function metal layer has the gradient composition, the second type work function metal layer includes aluminum and titanium, and a ratio of the aluminum to the titanium increases from a top of the second type work function metal layer to a bottom of the second type work function metal layer.

In some embodiments, the first type work function metal layer has a first gradient composition, and the second type work function metal layer has a second gradient composition. In some embodiments, the first type work function metal layer incudes a first metal and a second metal, wherein an amount of the second metal decreases along a gate height direction from a top of the first type work function metal layer to a bottom of the first type work function metal layer, the second type work function metal layer includes the first metal and a non-metal constituent, and an amount of non-metal constituent increases along the gate height direction from a top of the second type work function metal layer to a bottom of the second type work function metal layer. The bottom of the first type work function metal layer and the top of the second type work function metal layer may share an interface. In some embodiments, the bottom of the first type work function metal layer abuts the top of the second type work function metal layer. In some embodiments, the gate includes a work function barrier layer disposed between the first type work function metal layer and the second type work function metal layer. In some embodiments, the work function barrier layer abuts the bottom of the first type work function metal layer and the top of the second type work function metal layer, and the interface includes the work function barrier layer. In some embodiments, the work function barrier layer includes the first metal, the non-metal constituent, and a third metal.

Another exemplary stacked device structure includes a gate and a semiconductor layer stack. The semiconductor layer stack is disposed over a substrate, and the semiconductor layer stack includes a first semiconductor layer disposed over a second semiconductor layer. The gate includes a first gate dielectric layer and a second gate dielectric layer. The first gate dielectric layer is disposed over the first semiconductor layer, and the second gate dielectric layer is disposed over the second semiconductor layer. The gate further includes a p-type work function metal layer disposed over the second gate dielectric layer and around the second semiconductor layer. The gate further includes an n-type work function metal layer disposed over the first gate dielectric layer and around the first semiconductor layer. The n-type work function metal layer is disposed on the p-type work function metal layer. The n-type work function metal layer includes a first metal and a second metal, the p-type work function metal layer includes the first metal and nitrogen, and a portion of the p-type work function metal layer abutting the n-type work function metal layer further includes a third metal.

In some embodiments, the first metal is titanium, the second metal is aluminum, and the third metal is molybdenum. In some embodiments, the first metal is titanium, the second metal is aluminum, and the third metal is tungsten.

In some embodiments, the p-type work function metal layer is a molybdenum-doped titanium nitride layer that includes a titanium nitride sublayer and a titanium molybdenum nitride sublayer. In such embodiments, the titanium molybdenum nitride sublayer is the portion of the p-type work function metal layer abutting the n-type work function metal layer. In some embodiments, the p-type work function metal layer is a molybdenum-doped titanium nitride layer that includes a titanium nitride sublayer, a titanium molybdenum nitride sublayer disposed on the titanium nitride sublayer, and a molybdenum nitride sublayer disposed on the titanium molybdenum nitride sublayer. In such embodiments, the molybdenum nitride sublayer is the portion of the p-type work function metal layer abutting the n-type work function metal layer. In some embodiments, the p-type work function metal layer is a molybdenum-doped titanium nitride layer that includes a titanium molybdenum nitride sublayer and a molybdenum nitride sublayer. In such embodiments, the molybdenum nitride sublayer is the portion of the p-type work function metal layer abutting the n-type work function metal layer.

An exemplary method includes forming a first gate dielectric over a lower channel structure and a second gate dielectric over an upper channel structure. A channel stack includes the upper channel structure over the lower channel structure. The method further includes forming a first type work function layer having a first gradient composition over the first gate dielectric and forming a second type work function layer having a second gradient composition over the second gate dielectric. In some embodiments, the method further includes forming a work function barrier layer over the first type work function layer before forming the second type work function layer. In some embodiments, the first type work function layer is a titanium nitride layer, and the titanium nitride layer has a ratio of nitrogen to titanium that increases along a thickness of the first type work function layer. In some embodiments, the second type work function layer is a titanium aluminum layer, and the titanium aluminum layer has a ratio of aluminum to titanium that decreases along a thickness of the second type work function layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A stacked device structure comprising:
a semiconductor layer stack disposed over a substrate, wherein the semiconductor layer stack includes a first semiconductor layer of first device disposed over a second semiconductor layer of a second device, wherein the first device is disposed over the second device; and
a gate that includes:
a first gate dielectric layer and a second gate dielectric layer, wherein the first gate dielectric layer is disposed over the first semiconductor layer and the second gate dielectric layer is disposed over the second semiconductor layer,
a first type work function metal layer and a second type work function metal layer, wherein the first type work function metal layer is disposed over the first gate dielectric layer and the second type work function metal layer is disposed over the second gate dielectric layer, and
at least one of the first type work function metal layer or the second type work function metal layer has a gradient composition.

2. The stacked device structure of claim 1, wherein:
the second type work function metal layer has the gradient composition;
the second type work function metal layer includes nitrogen and titanium; and
a ratio of the nitrogen to the titanium increases from a top of the second type work function metal layer to a bottom of the second type work function metal layer.

3. The stacked device structure of claim 1, wherein:
the first type work function metal layer has the gradient composition;
the first type work function metal layer includes nitrogen and titanium; and
a ratio of the nitrogen to the titanium decreases from a top of the first type work function metal layer to a bottom of the first type work function metal layer.

4. The stacked device structure of claim 1, wherein:
the first type work function metal layer has the gradient composition;
the first type work function metal layer includes aluminum and titanium; and
a ratio of the aluminum to the titanium decreases from a top of the first type work function metal layer to a bottom of the first type work function metal layer.

5. The stacked device structure of claim 1, wherein:
the second type work function metal layer has the gradient composition;
the second type work function metal layer includes aluminum and titanium; and
a ratio of the aluminum to the titanium increases from a top of the second type work function metal layer to a bottom of the second type work function metal layer.

6. The stacked device structure of claim 1, wherein:
the first type work function metal layer has a first gradient composition; and
the second type work function metal layer has a second gradient composition.

7. The stacked device structure of claim 6, wherein:
the first type work function metal layer incudes a first metal and a second metal, wherein an amount of the second metal decreases along a gate height direction from a top of the first type work function metal layer to a bottom of the first type work function metal layer; and
the second type work function metal layer includes the first metal and a non-metal constituent, wherein an amount of non-metal constituent increases along the gate height direction from a top of the second type work function metal layer to a bottom of the second type work function metal layer, wherein the bottom of the first type work function metal layer and the top of the second type work function metal layer share an interface.

8. The stacked device structure of claim 7, wherein the bottom of the first type work function metal layer abuts the top of the second type work function metal layer.

9. The stacked device structure of claim 7, wherein the gate includes a work function barrier layer, wherein the work function barrier layer is disposed between the first type work function metal layer and the second type work function metal layer, the work function barrier layer abuts the bottom of the first type work function metal layer and the top of the second type work function metal layer, and the interface includes the work function barrier layer.

10. The stacked device structure of claim 9, wherein the work function barrier layer includes the first metal, the non-metal constituent, and a third metal.

11. The stacked device structure of claim 1, wherein the first type work function metal layer is disposed around the first semiconductor layer, and the second type work function metal layer is disposed around the second semiconductor layer.

12. A stacked device structure comprising:
a semiconductor layer stack disposed over a substrate, wherein the semiconductor layer stack includes a first semiconductor layer disposed over a second semiconductor layer; and
a gate that includes:
a first gate dielectric layer and a second gate dielectric layer, wherein the first gate dielectric layer is disposed over the first semiconductor layer and the second gate dielectric layer is disposed over the second semiconductor layer,
a p-type work function metal layer disposed over the second gate dielectric layer and around the second semiconductor layer,
an n-type work function metal layer disposed over the first gate dielectric layer and around the first semiconductor layer, wherein the n-type work function metal layer is disposed on the p-type work function metal layer,
wherein the n-type work function metal layer includes a first metal and a second metal, the p-type work function metal layer includes the first metal and nitrogen, and a portion of the p-type work function metal layer abutting the n-type work function metal layer further includes a third metal.

13. The stacked device structure of claim 12, wherein the first metal is titanium, the second metal is aluminum, and the third metal is molybdenum.

14. The stacked device structure of claim 13, wherein the p-type work function metal layer is a molybdenum-doped titanium nitride layer that includes:
a titanium nitride sublayer; and
a titanium molybdenum nitride sublayer disposed on the titanium nitride sublayer, wherein the titanium molybdenum nitride sublayer is the portion of the p-type work function metal layer abutting the n-type work function metal layer.

15. The stacked device structure of claim 13, wherein the p-type work function metal layer is a molybdenum-doped titanium nitride layer that includes:
a titanium nitride sublayer;
a titanium molybdenum nitride sublayer disposed on the titanium nitride sublayer; and
a molybdenum nitride sublayer disposed on the titanium molybdenum nitride sublayer, wherein the molybdenum nitride sublayer is the portion of the p-type work function metal layer abutting the n-type work function metal layer.

16. The stacked device structure of claim 13, wherein the p-type work function metal layer is a molybdenum-doped titanium nitride layer that includes:
a titanium molybdenum nitride sublayer; and
a molybdenum nitride sublayer disposed on the titanium molybdenum nitride sublayer, wherein the molybdenum nitride sublayer is the portion of the p-type work function metal layer abutting the n-type work function metal layer.

17. The stacked device structure of claim 12, wherein the first metal is titanium, the second metal is aluminum, and the third metal is tungsten.

18. A method comprising:
forming a first gate dielectric over a lower channel structure and a second gate dielectric over an upper channel structure, wherein a channel stack includes the upper channel structure over the lower channel structure;
forming a first type work function layer having a first gradient composition over the first gate dielectric; and
forming a second type work function layer having a second gradient composition over the second gate dielectric.

19. The method of claim 18, further comprising forming a work function barrier layer over the first type work function layer before forming the second type work function layer.

20. The method of claim 18, wherein:
the first type work function layer is a titanium nitride layer having a ratio of nitrogen to titanium that increases along a thickness of the first type work function layer; and
the second type work function layer is a titanium aluminum layer having a ratio of aluminum to titanium that decreases along a thickness of the second type work function layer.
